(19) United States
(12) Patent Application Publication
(10) Pub. No.: US 2026/0059946 A1
(43) Pub. Date: Feb. 26, 2026

(54) DISPLAY PANEL AND DISPLAY DEVICE

(71) Applicants: Hefei Visionox Technology Co., Ltd., Hefei (CN); VISIONOX TECHNOLOGY INC., Suzhou (CN)

(72) Inventors: Yuan YAO, Hefei (CN); Aihua XUE, Hefei (CN)

(73) Assignees: Hefei Visionox Technology Co., Ltd., Hefei (CN); VISIONOX TECHNOLOGY INC., Suzhou (CN)

(21) Appl. No.: 19/305,884

(22) Filed: Aug. 21, 2025

(30) Foreign Application Priority Data
Aug. 21, 2024 (CN) 202411156473.0

(51) Int. Cl. H10K 59/122; H10K 59/35; H10K 59/38; H10K 59/40; H10K 59/80

(52) U.S. Cl. CPC H10K 59/122; H10K 59/352; H10K 59/353; H10K 59/38; H10K 59/40; H10K 59/873; H10K 59/8792

(57) ABSTRACT

A display panel and a display device. The display panel is divided into a display region and a non-display region connected to each other. The display panel includes a substrate, an isolation structure and a light-emitting layer. The isolation structure is disposed on a side of the substrate, and isolation openings are enclosed and formed by the isolation structure. The light-emitting layer includes light-emitting units located in the isolation openings of the display region. The isolation structure located in the display region includes a first isolation segment and a second isolation segment, an orthographic projection of the first isolation segment on the substrate and an orthographic projection of the second isolation segment on the substrate are located between orthographic projections of two adjacent isolation openings on the substrate, and a width of the first isolation segment is greater than a width of the second isolation segment.

### CROSS-REFERENCE TO RELATED APPLICATION

This application claims priority to Chinese Patent Application No. 202411156473.0 filed Aug. 21, 2024, the disclosure of which is incorporated herein by reference in its entirety.

### FIELD

The present application belongs to the field of display technologies, and in particular to, a display panel and a display device.

### BACKGROUND

Organic light-emitting diodes (OLEDs) and planar display devices based on technologies such as a light-emitting diode (LED) technology are widely used in various consumer electronic products such as a mobile phone, a television, a notebook computer, and a desktop computer because of advantages such as high picture quality, power saving, a thin body, and a wide application scope, and have become the mainstream in display devices.

However, the display performance of current OLED display products needs to be improved.

### SUMMARY

Embodiments of the present application provide a display panel and a display device, to improve the process performance of the display panel.

An embodiment of a first aspect of the embodiments of the present application provides a display panel. The display panel is divided into a display region and a non-display region connected to each other. The display panel includes a substrate, an isolation structure and a light-emitting layer. The isolation structure is disposed on a side of the substrate, and isolation openings are disposed on the isolation structure. The light-emitting layer includes light-emitting units located in the isolation openings of the display region. The isolation structure located in the display region includes a first isolation segment and a second isolation segment, an orthographic projection of the first isolation segment on the substrate and an orthographic projection of the second isolation segment on the substrate are located between orthographic projections of two adjacent isolation openings on the substrate, the first isolation segment has a first width, the second isolation segment has a second width, and the first width is greater than the second width.

An embodiment of a first aspect of the embodiments of the present application provides a display panel. The display panel is divided into a display region and a non-display region connected to each other. The display panel includes a substrate, a pixel defining layer and an isolation structure. The pixel defining layer is disposed on the substrate and includes a pixel defining portion and pixel openings. The isolation structure is disposed on a side of the pixel defining portion facing away from the substrate, isolation openings are disposed on the isolation structure, and the isolation openings communicates with the pixel openings. The pixel defining portion located in the display region includes a first defining section and a second defining section, an orthographic projection of the first defining section on the substrate and an orthographic projection of the second defining section on the substrate are located between orthographic projections of two adjacent pixel openings on the substrate, the first defining section has a third width, the second defining section has a fourth width, and the third width is greater than the fourth width.

In an embodiment, the first isolation segment and the second isolation segment are located between a same group of two adjacent isolation openings among the plurality of isolation openings; and an extension direction of the first isolation segment is the same as an extension direction of the second isolation segment. Two adjacent isolation openings include a first sub-isolation opening and a second sub-isolation opening, the first sub-isolation opening includes a first side wall, the second sub-isolation opening includes a second side wall, the first side wall and the second side wall are disposed opposite to each other, and the first isolation segment and the second isolation segment are located between the first side wall and the second side wall; a width of the first isolation segment in an arrangement direction of two adjacent isolation openings located on two sides of the first isolation segment is the first width, and a width of the second isolation segment in an arrangement direction of two adjacent isolation openings located on two sides of the second isolation segment is the second width; and the first isolation segment is connected to the second isolation segment.

In an embodiment, one of two isolation openings located on two sides of the first isolation segment and one of two isolation openings located on two sides of the second isolation segment are a same isolation opening; the plurality of isolation openings include a first sub-isolation opening, a second sub-isolation opening and a third sub-isolation opening, where the second sub-isolation opening is disposed adjacent to the first isolation opening, and the second sub-isolation opening is also disposed adjacent to the third sub-isolation opening; the first sub-isolation opening includes a first side wall, the second sub-isolation opening includes a second side wall and a third side wall, and the third sub-isolation opening includes a fourth side wall, where the first side wall and the second side wall are disposed opposite to each other, the third side wall and the fourth side wall are disposed opposite to each other, the first isolation segment is located between the first side wall and the second side wall, and the second isolation segment is between the third side wall and the fourth side wall; a width of the first isolation segment in an arrangement direction of the first sub-isolation opening and the second sub-isolation opening is the first width, and a width of the second isolation segment in an arrangement direction of the second sub-isolation opening and the third sub-isolation opening is the second width; an extension direction of the first isolation segment is different from an extension direction of the second isolation segment; and the first isolation segment is connected to the second isolation segment.

In an embodiment, two isolation openings located on two sides of the first isolation segment are different from two isolation openings located on two sides of the second isolation segment; the plurality of isolation openings include a first sub-isolation opening, a second sub-isolation opening, a third sub-isolation opening and a fourth sub-isolation opening, where the second sub-isolation opening is disposed adjacent to the first isolation opening, the third sub-isolation opening is disposed adjacent to the fourth sub-isolation opening, the first sub-isolation opening includes a first side wall, the second sub-isolation opening includes a second side wall, the third sub-isolation opening includes a fourth side wall, and the fourth sub-isolation opening includes a fifth side wall, where the first side wall and the second side wall are disposed opposite to each other, the first isolation segment is located between the first side wall and the second side wall, the fourth side wall and the fifth side wall are disposed opposite to each other, and the second isolation segment is located between the fourth side wall and the fifth side wall; a width of the first isolation sub-segment in an arrangement direction of the first sub-isolation opening and the second sub-isolation opening is the first width, and a width of the second isolation segment in an arrangement direction of the third sub-isolation opening and the fourth sub-isolation opening is the second width; and the orthographic projection of the first isolation segment on the substrate and the orthographic projection of the second isolation segment on the substrate are disposed at intervals.

In an embodiment, the display panel further includes a first display region and a second display region, a pixel density of the first display region is less than a pixel density of the second display region, the first isolation segment is located in the first display region, and the second isolation segment is located in the second display region; the first isolation segment includes a first sub-segment located in the first display region, the second isolation segment includes a second sub-segment located in the second display region; an extension direction of the first sub-segment is the same as an extension direction of the second sub-segment, the first sub-segment has the first width, and the second sub-segment has the second width; the plurality of isolation openings include a first isolation opening and a second isolation opening which are located in the first display region, and a third isolation opening and a fourth isolation opening which are located in the second display region, an orthographic projection of the first sub-segment on the substrate is located between an orthographic projection of the first isolation opening adjacent to the second isolation opening on the substrate and an orthographic projection of the second isolation opening adjacent to the first isolation opening on the substrate, and an orthographic projection of the second sub-segment on the substrate is located between an orthographic projection of the third isolation opening adjacent to the fourth isolation opening on the substrate and an orthographic projection of the fourth isolation opening adjacent to the third isolation opening on the substrate; a width of the first sub-segment in an arrangement direction of the first isolation opening and the second isolation opening is the first width, and a width of the second sub-segment in an arrangement direction of the third isolation opening and the fourth isolation opening is the second width; the first isolation opening and the third isolation opening are configured to accommodate light-emitting units of a same color, and the second isolation opening and the fourth isolation opening are configured to accommodate light-emitting units of a same color; and an arrangement manner of the first isolation opening, the first sub-segment and the second isolation opening is the same as an arrangement manner of the third isolation opening, the second sub-segment and the fourth isolation opening.

In an embodiment, the plurality of light-emitting units include a first light-emitting unit, a second light-emitting unit and a third light-emitting unit; the plurality of the isolation openings form a plurality of opening repeating unit, the plurality of opening repeating unit include a first opening group and a second opening group disposed side by side in a first direction, the first opening group includes a second opening portion and a third opening portion arranged in a second direction, the second opening group includes a first opening portion extending in the second direction, the first light-emitting unit is located at the first opening portion, the second light-emitting unit is located at the second opening portion, and the third light-emitting unit is located at the third opening portion; the first isolation segment is located between the second opening portion of the first opening group and the third opening portion of the first opening group; and the second isolation segment is located between the first opening portion and the second opening portion, or the second isolation segment is located between the first opening portion and the third opening portion.

In an embodiment, a light-emitting unit of the light-emitting units includes a first electrode, a light-emitting structure and a second electrode, where the first electrode, the light-emitting structure and the second electrode are disposed in a stacked manner in a direction facing away from the substrate; and the substrate includes a plurality of drive unit s and a first insulating layer disposed on a side of the a drive unit facing the light-emitting layer, the first insulating layer is provided with a plurality of connection via holes, and the first electrode and the drive unit are electrically connected to each other via a respective connection via hole among the plurality of the connection via holes. Orthographic projections of the connection via holes on the substrate at least partially overlap with an orthographic projection of at least one first isolation segment on the substrate. The orthographic projections of the connection via holes on the substrate are located within the orthographic projection of the first isolation segment on the substrate. The first electrode includes a body portion and a protruding portion formed by protruding the body portion, and the protruding portion is via connected to the drive unit via a respective connection via hole of the connection via holes; the protruding portion protrudes from the body portion in a first preset direction, an extension width of the body portion in a second preset direction is greater than an extension width of the protruding portion in the second preset direction, and the second preset direction intersects the first preset direction; the first isolation segment is provided with a light-transmitting hole, and the orthographic projections of the connection via holes on the substrate at least partially overlap with an orthographic projection of at least one first isolation segment provided with the light-transmitting hole on the substrate; and the orthographic projections of the connection via holes on the substrate are located within an orthographic projection of the first isolation segment provided with the light-transmitting hole, on the substrate.

In an embodiment, orthographic projections of connection via holes corresponding to at least two first electrodes on the substrate at least partially overlap with an orthographic projection of a same first isolation segment on the substrate; or orthographic projections of connection via holes corresponding to at least two first electrodes on the substrate are located within an orthographic projection of a same first isolation segment on the substrate.

In an embodiment, at least part of the first isolation segment is provided with a light-transmitting hole; and the orthographic projection of the second isolation segment on the substrate is staggered with an orthographic projection of the light-transmitting hole on the substrate. The display region includes a third display region and a fourth display region connected to each other, a light transmittance of the third display region is greater than a light transmittance of the fourth display region, the first isolation segment includes a fifth sub-segment located in the third display region, and the fifth sub-segment is provided with the light-transmitting hole; the first isolation segment further includes a sixth sub-segment located in the fourth display region, and an orthogonal projection of the sixth sub-segment on the substrate is staggered with the orthographic projection of the light-transmitting hole on the substrate; and the second isolation segment is located in at least one of the third display region or the fourth display region.

In an embodiment, the plurality of light-emitting units include a first light-emitting unit, a second light-emitting unit and a third light-emitting unit, the plurality of isolation openings include a first opening portion, a second opening portion and a third opening portion, the first light-emitting unit is located at the first opening portion, the second light-emitting unit is located at the second opening portion, and the third light-emitting unit is located at the third opening portion; two first opening portions and two second opening portions are alternately located at four corners of a first virtual quadrangle, and the third opening portion is located within the first virtual quadrangle; the light-transmitting hole is located on at least one side of the first virtual quadrangle, and the light-transmitting hole is located between the first opening portion and the second opening portion adjacent to each other; the first virtual quadrangle includes a top side, a bottom side and two lateral sides connecting the top side and the bottom side, the light-transmitting hole includes a first sub-hole and a second sub-hole, the first sub-hole is located on at least one of the top side and the bottom side, and the second sub-hole is located on the lateral sides; and the first isolation sub-segment includes a seventh sub-segment and an eighth sub-segment, the seventh sub-segment is provided with the first sub-hole, and the eighth sub-segment is provided with the second sub-hole.

In an embodiment, the display panel further includes a pixel defining layer disposed on the substrate, where the isolation structure is located on a side of the pixel defining layer facing away from the substrate, the pixel defining layer includes a pixel defining portion and a pixel opening are enclosed and formed by the pixel defining portion, the pixel opening communicates with a respective isolation opening, the pixel defining portion includes a first defining section and a second defining section, an orthographic projection of the first isolation segment on the substrate is located within an orthographic projection of the first defining section on the substrate, an orthographic projection of the second isolation segment on the substrate is located within an orthographic projection of the second defining section on the substrate, the first defining section has a third width, the second defining section has a fourth width, and the third width is greater than the fourth width. In the pixel openings and the plurality of isolation openings communicating with each other, orthographic projections of edges of the pixel openings on the substrate are located within orthographic projection contours of edges of the plurality of isolation openings on the substrate; or in the pixel openings and the plurality of isolation openings communicating with each other, orthographic projections of edges of the pixel openings on the substrate and orthographic projections of edges of the plurality of isolation openings on the substrate are at least partially disposed at equal intervals.

In an embodiment, the display panel further includes a first encapsulation layer, where the first encapsulation layer includes a plurality of first encapsulation portions, the plurality of first encapsulation portions are located on a side of the plurality of light-emitting units facing away from the substrate, a first encapsulation portion of the plurality of first encapsulation portions extend from a respective isolation opening of the plurality of isolation openings to a side of the isolation structure facing away from the substrate. At least one of the following is satisfied: a sealing gap located on the side of the isolation structure facing away from the substrate is formed between two adjacent first encapsulation portions among the plurality of first encapsulation portions, the sealing gap located on a side of the first isolation segment facing away from the substrate has a fifth width, the sealing gap on a side of the second isolation segment facing away from the substrate has a sixth width, and the fifth width is greater than the sixth width; and orthographic projection areas of at least two first encapsulation portions among the plurality of first encapsulation portions on the substrate are different. An isolation opening of the plurality of isolation openings includes a first opening portion, a second opening portion and a third opening portion, an orthographic projection area of the first opening portion on the substrate is greater than an orthographic projection area of the second opening portion on the substrate, and the orthographic projection area of the second opening portion on the substrate is greater than an orthographic projection area of the third opening portion on the substrate; and the first encapsulation portion includes a first encapsulation unit covering at least part of the first opening portion, a second encapsulation unit covering at least part of the second opening portion, and a third encapsulation unit covering at least part of the third opening portion, an orthographic projection area of the first encapsulation unit on the substrate is greater than an orthographic projection area of the second encapsulation unit on the substrate, and the orthographic projection area of the second encapsulation unit on the substrate is greater than an orthographic projection area of the third encapsulation unit on the substrate.

An embodiment of a second aspect of the present application further provides a display device. The display device includes any one display panel of the display panels in the first aspect of the present application.

In the above-described display panel provided in the present application, the display panel includes the substrate, the isolation structure, and the light-emitting layer. The isolation openings are enclosed and formed by the isolation structure, the light-emitting units of the light-emitting layer are located within the isolation openings of the display region, the light-emitting units are used for achieving the light-emitting display of the display region of the display panel, and the isolation structure is used for improving the color mixing problem between adjacent light-emitting units. The isolation structure of the display region includes the first isolation segment and the second isolation segment, and the first width of the first isolation segment is greater than the second width of the second isolation segment, that is, the isolation structure includes two parts with different widths. Widths of the isolation segments in different regions of the isolation structure are adjusted, so that dimensions of the isolation openings in different regions can be adjusted, and further the display effect of the display panel can be adjusted, thereby improving the use performance of the display panel.

### BRIEF DESCRIPTION OF DRAWINGS

FIG. 1 is a schematic structural diagram of a display panel according to an embodiment of the present application;

FIG. 2 is a partial top view of a display panel according to an embodiment of the present application;

FIG. 3 is a sectional view of A-A of FIG. 2 in an example;

FIG. 4 is a sectional view of B-B of FIG. 2 in an example;

FIG. 5 is a partial top view of a display panel according to another embodiment of the present application;

FIG. 6 is a partial top view of a display panel according to still another embodiment of the present application;

FIG. 7 is a partial top view of an isolation structure of a display panel according to still another embodiment of the present application;

FIG. 8 is a sectional view of C-C of FIG. 6;

FIG. 9 is a partial top view of a display panel according to still another embodiment of the present application;

FIG. 10 is a partial top view of a display panel according to yet another embodiment of the present application;

FIG. 11 is a partial top view of a display panel according to still another embodiment of the present application;

FIG. 12 is a partial top view of an isolation structure of a display panel according to still another embodiment of the present application;

FIG. 13 is a sectional view of D-D of FIG. 11;

FIG. 14 is a sectional view of E-E of FIG. 11;

FIG. 15 is a partial top view of a display panel according to yet another embodiment of the present application;

FIG. 16 is a partial top view of an isolation structure of a display panel according to yet another embodiment of the present application;

FIG. 17 is a sectional view of A-A of FIG. 2 in another example;

FIG. 18 is a sectional view of B-B of FIG. 2 in another example;

FIG. 19 is a partial top view of a display panel according to yet another embodiment of the present application;

FIG. 20 is a sectional view of A-A of FIG. 2 in still another example; and

FIG. 21 is a sectional view of B-B of FIG. 2 in still another example.

### DETAILED DESCRIPTION

Features of various aspects and exemplary embodiments of the present application will be described in detail below.

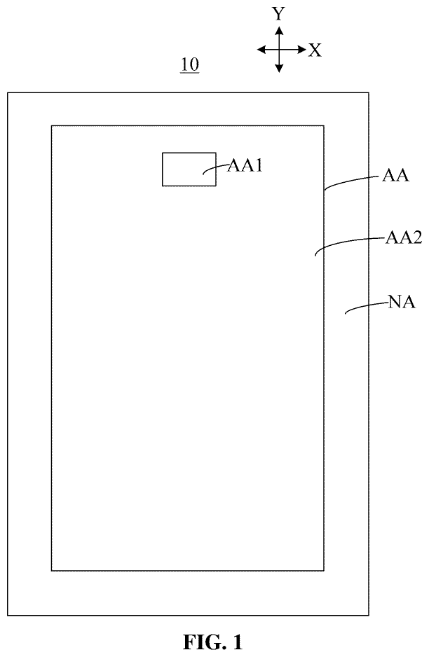

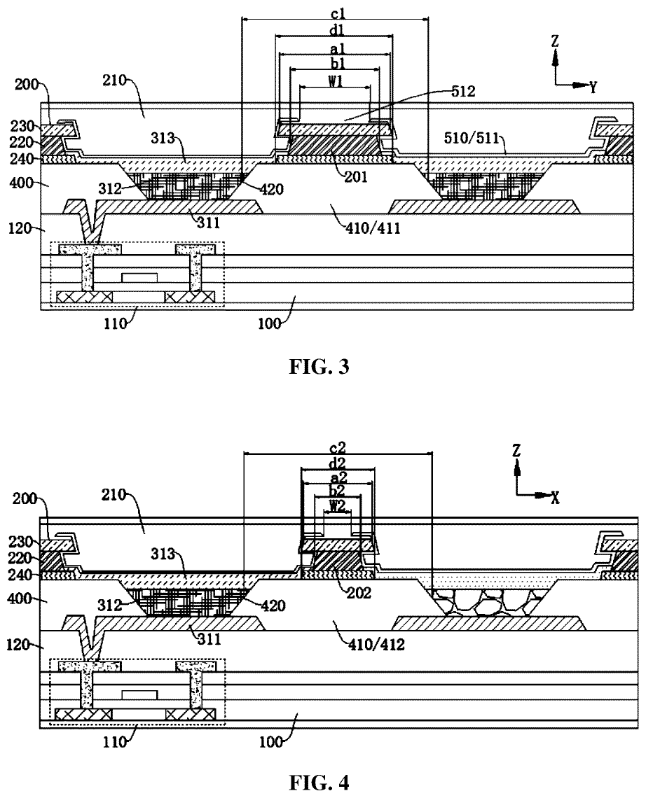

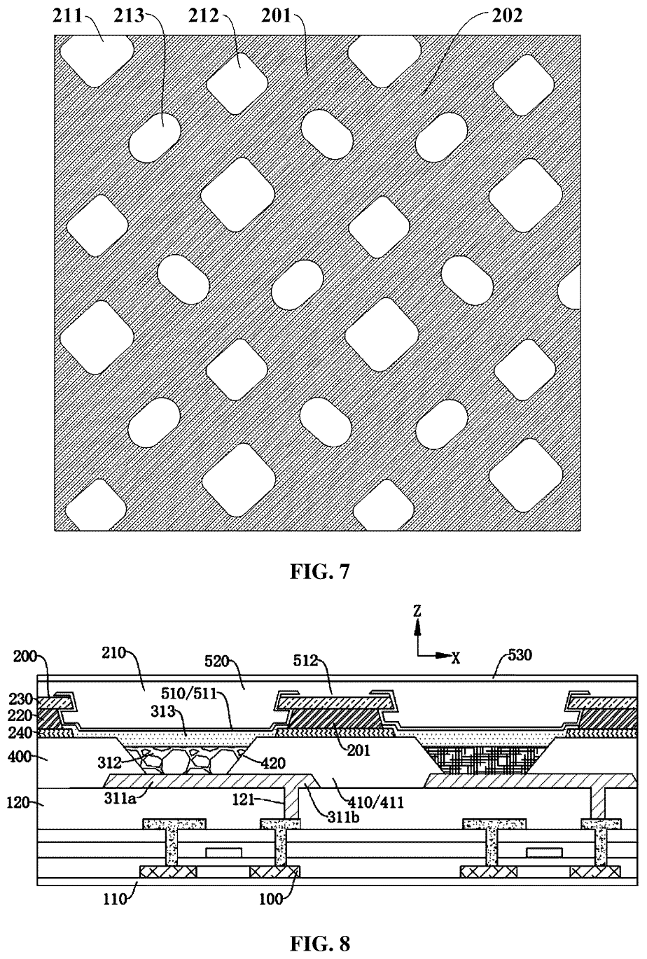

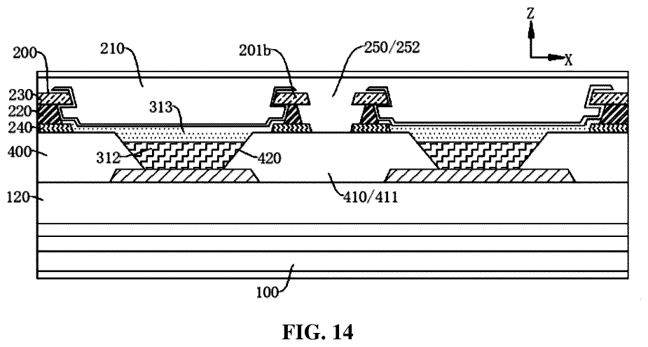

To better understand the present application, the display panel 10 and the display device according to the embodiments of the present application will be described in detail below in conjunction with FIG. 1 to FIG. 21. The composition, preparation, and the like of the isolation structure 200 mentioned below are further described in patents CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072 and CN116685174A, which are incorporated herein by reference.

Referring to FIGS. 1 to 4, an embodiment of the present application provides a display panel 10. The display panel 10 is divided into a display region AA and a non-display region NA connected to each other. The display panel 10 includes a substrate 100, a light-emitting layer 300 and an isolation structure 200. The isolation structure 200 is disposed on a side of the substrate 100, and an isolation opening 210 is disposed on the isolation structure 200. The light-emitting layer 300 includes a light-emitting unit 310 located in the isolation opening 210 of the display region AA. The isolation structure 200 located in the display region AA includes a first isolation segment 201 and a second isolation segment 202. An orthographic projection of the first isolation segment 201 on the substrate 100 and an orthographic projection of the second isolation segment 202 on the substrate 100 are located between orthographic projections of two adjacent isolation openings 210 on the substrate 100. The first isolation segment 201 has a first width d1, the second isolation segment 202 has a second width d2, and the first width d1 being greater than the second width d2.

In the above-described display panel 10 provided in the present application, the display panel 10 includes the substrate 100, the isolation structure 200 and the light-emitting layer 300. The isolation opening 210 is disposed on the isolation structure 200, the light-emitting unit 310 of the light-emitting layer 300 is located within the isolation opening 210, the light-emitting unit 310 is used for achieving the light-emitting display of the display panel 10, and the isolation structure 200 is used for improving the color mixing problem between adjacent light-emitting units 310. The isolation structure 200 includes the first isolation segment 201 and the second isolation segment 202, where the first width d1 of the first isolation segment 201 is greater than the second width d2 of the second isolation segment 202, that is, the isolation structure 200 includes two parts with different widths. Widths of the isolation segments in different regions of the isolation structure 200 are adjusted, so that dimensions of the isolation openings 210 in different regions can be adjusted, and further the display effect of the display panel 10 can be adjusted, thereby improving the use performance of the display panel 10.

In one embodiment, the first isolation segment 201 and the second isolation segment 202 are both located between two adjacent isolation openings 210, and the first isolation segment 201 and the second isolation segment 202 are disposed in various forms. For example, the first isolation segment 201 may be in a ring shape or a semi-ring shape and the like surrounding a certain isolation opening 210, and the first isolation segment 201 may also be in a strip shape located on a side of the isolation opening 210. Likewise, the second isolation segment 202 may be in a ring shape or a semi-ring shape and the like surrounding a certain isolation opening 210, and the second isolation segment 202 may also be in a strip shape located on a side of the isolation opening 210.

In one embodiment, multiple first isolation segments 201 and multiple second isolation segments 202 may be connected to each other in a mesh structure.

In one embodiment, the display panel 10 further includes a pixel defining layer 400. The pixel defining layer 400 is disposed on the substrate 100. The pixel defining layer 400 includes a pixel defining portion 410 and a pixel opening 420. The pixel opening 420 communicates with the isolation opening 210, and at least part of the light-emitting unit 310 may be located within the pixel opening 420 in the isolation opening 210. The isolation structure 200 may be located on a side of the pixel defining portion 410 facing away from the substrate 100, or the pixel defining portion 410 is provided with an avoidance opening, and the isolation structure 200 is in direct contact with and connected to the substrate 100 in the avoidance opening.

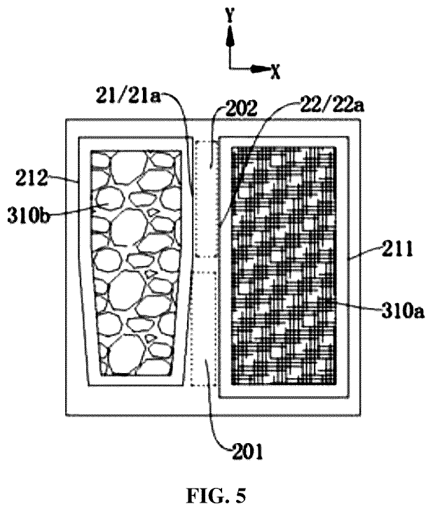

In one embodiment, as shown in FIG. 5, the first isolation segment 201 and the second isolation segment 202 may also be located between the same group of two adjacent isolation openings 210. For example, the first isolation segment 201 and the second isolation segment 202 that are sequentially distributed in a second direction Y are disposed between two isolation openings 210 disposed at intervals in a first direction X.

In one embodiment, two adjacent isolation openings 210 include a first sub-isolation opening 21and a second sub-isolation opening 22. The first sub-isolation opening 21 includes a first side wall 21a, the second sub-isolation opening 22 includes a second side wall 22a, the first side wall 21a and the second side wall 22a are disposed opposite to each other, and the first isolation segment 201 and the second isolation segment 202 are located between the first side wall 21a and the second side wall 22a. Optionally, the first side wall 21a and the second side wall 22a being disposed opposite to each other means that the first side wall 21a and the second side wall 22a are disposed side by side in a certain direction. Optionally, the first side wall 21a and the second side wall 22a may be parallel or non-parallel to each other.

In one embodiment, the first width d1 of the first insulation segment 201 may be a distance between the first side wall 21a and the second side wall 22a which are located on two sides of the first insulation segment 201. The second width d2 of the second insulation segment 202 may be a distance between the first side wall 21a and the second side wall 22a which are located on two sides of the second insulation segment 202.

In one embodiment, a width of the first isolation segment 201 in an arrangement direction of two adjacent isolation openings 210 located on two sides of the first isolation segment 201 is the first width d1, exemplarily, a minimum width of the first isolation segment 201 in the arrangement direction of the two adjacent isolation openings 210 located on the two sides of the first isolation segment 201 may be selected to be the first width d1. A width of the second isolation segment 202 in an arrangement direction of two adjacent isolation openings 210 located on two sides of the second isolation segment 202 is the second width d2, exemplarily, a minimum width of the second isolation segment 202 in the arrangement direction of the two adjacent isolation openings 210 located on the two sides of the second isolation segment 202 may be selected to be the second width d2.

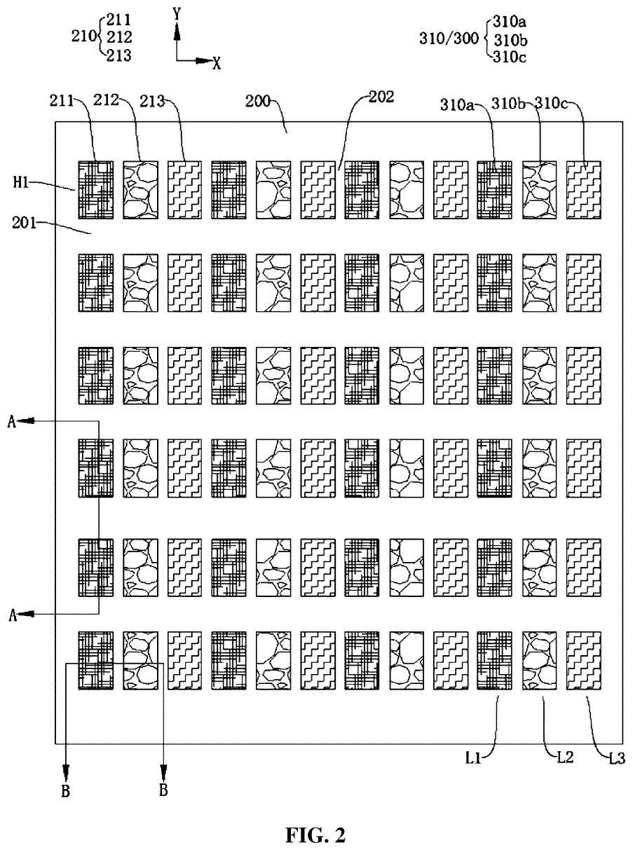

In one embodiment, the first width d1 may also be an extension dimension of the first insulation segment 201 in a direction perpendicular to an extension direction of the first insulation segment 201. As shown in FIG. 2, when the first isolation segment 201 is located between two isolation openings 210 disposed side by side in the second direction Y, the first isolation segment 201 extends in a strip shape in the first direction X, a width direction of the first isolation segment 201 is the second direction Y, the second direction Y is perpendicular to the first direction X, and the first width d1 is an extension dimension of the first isolation segment 201 in the second direction Y. A width direction of the second isolation segment 202 is disposed in the same manner as the first isolation segment 201, which will not be repeated here. Optionally, when the first isolation segment 201 and the second isolation segment 202 are located between two adjacent isolation openings 210 in the same group, an extension direction of the first isolation segment 201 is the same as an extension direction of the second isolation segment 202. For example, as shown in FIG. 5, the first isolation segment 201 and the second isolation segment 202 sequentially distributed in the second direction Y are disposed between two isolation openings 210 disposed at intervals in the first direction X, and the first isolation segment 201 and the second isolation segment 202 may extend in the second direction Y. Optionally, the first isolation segment 201 and the second isolation segment 202 may be connected to each other.

In these embodiments, the first isolation segment 201 and the second isolation segment 202 having different widths may also be disposed between two adjacent isolation openings 210 in the same group, to precisely adjust the dimensions of the isolation openings 210 in different regions, thereby further adjusting the display effect of the display panel 10 and improving the use performance of the display panel 10.

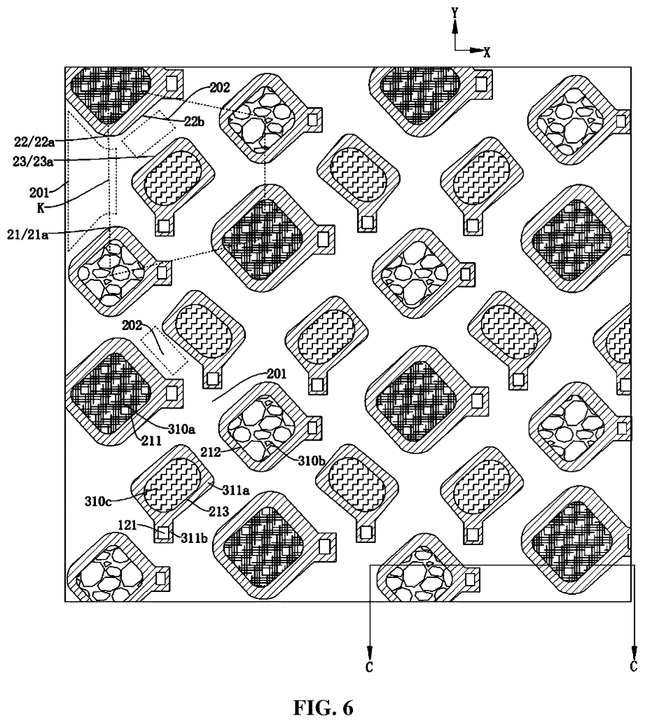

In one embodiment, in another some optional embodiments, as shown in FIGS. 1 and 6, at least one of two isolation openings 210 located on two sides of the first isolation segment 201 and at least one of two isolation openings 210 located on two sides of the second isolation segment 202 are the same isolation opening 210, for example, the two isolation openings 210 located on the two sides of the first isolation segment 201 are completely different from the two isolation openings 210 located on the two sides of the second isolation segment 202, that is, the first isolation segment 201 and the second isolation segment 202 may be used to enclose an entirely different isolation opening 210. Optionally, two isolation openings 210 located on two sides of the first isolation segment 201 are the same as one of two isolation openings 210 located on two sides of the second isolation segment 202, that is, the first isolation segment 201 and the second isolation segment 202 may be used to enclose the same isolation opening 210, and the first isolation segment 201 and the second isolation segment 202 may be located on different sides of the same isolation opening 210.

In another some embodiments, as shown in FIGS. 1 to 4 and FIGS. 6 to 8, one of two isolation openings 210 located on two sides of the first isolation segment 201 and one of two isolation openings 210 located on two sides of the second isolation segment 202 are the same isolation opening 210. That is, the first isolation segment 201 and the second isolation segment 202 may be located on a peripheral side of the same isolation opening 210. The display effect of the display panel 10 can be adjusted by adjusting dimensions of the isolation structure 200 at different positions of the peripheral side of the same isolation opening 210.

In one embodiment, multiple isolation openings 210 include a first sub-isolation opening 21, a second sub-isolation opening 22 and a third sub-isolation opening 23, where the second sub-isolation opening 22 is disposed adjacent to the first isolation opening 210a, and the second sub-isolation opening 22 is disposed adjacent to the third sub-isolation opening 23. Optionally, the first isolation segment 201 may be located between the first sub-isolation opening 21 and the second sub-isolation opening 22, and the second isolation segment 202 may be located between the first sub-isolation opening 21 and the third sub-isolation opening 23. The first sub-isolation opening 21 is disposed on each of two sides of the first isolation segment 201 and the second isolation segment 202.

In one embodiment, the first sub-isolation opening 21 includes a first side wall 21a, and the second sub-isolation opening 22 includes a second side wall 22a and a third side wall 22b, the third sub-isolation opening 23 includes a fourth side wall 23a. The first side wall 21a and the second side wall 22a are disposed opposite to each other, the third side wall 22b and the fourth side wall 23a are disposed opposite to each other, the first isolation segment 201 is located between the first side wall 21a and the second side wall 22a, the second isolation segment 202 is located between the third side wall 22b and the fourth side wall 23a, so that the one of the two isolation openings 210 located on the two sides of the first isolation segment 201 and the one of the two isolation openings 210 located on the two sides of the second isolation segment 202 are the same isolation opening 210. The third side wall 22b and the fourth side wall 23a being disposed opposite to each other is the same as the first side wall 21a and the second side wall 22a being disposed opposite to each other in the foregoing embodiment, which will not be repeated here.

In one embodiment, a width of the first isolation segment 201 in an arrangement direction of the first sub-isolation opening 21 and the second sub-isolation opening 22 is the first width d1, exemplarily, a minimum width of the first isolation segment 201 in the arrangement direction of the first sub-isolation opening 21 and the second sub-isolation opening 22 may be selected to be the first width d1. A width of the second isolation segment 202 in an arrangement direction of the second sub-isolation opening 22 and the third sub-isolation opening 23 is the second width d2, exemplarily, a minimum width of the second isolation segment 202 in the arrangement direction of the second sub-isolation opening 22 and the third sub-isolation opening 23 may be selected to be the second width d2.

In one embodiment, when the first isolation segment 201 and the second isolation segment 202 are located on the peripheral side of the same isolation opening 210, the extension direction of the first isolation segment 201 may be the same as or different from the extension direction of the second isolation segment 202. For example, as shown in FIG. 1, the first isolation segment 201 may be located on a side of the isolation opening 210 in the second direction Y and extend in the first direction X, and the second isolation segment 202 may be located on a side of the isolation opening 210 in the first direction X and extend in the second direction Y.

In one embodiment, the first isolation segment 201 and the second isolation segment 202 may be connected to each other. For example, the first isolation segment 201 may be located on a side of the isolation opening 210 in the first direction X, the second isolation segment 202 may be located on a side of the isolation opening 210 in the second direction Y, and the first isolation segment 201 and the second isolation segment 202 are connected to each other.

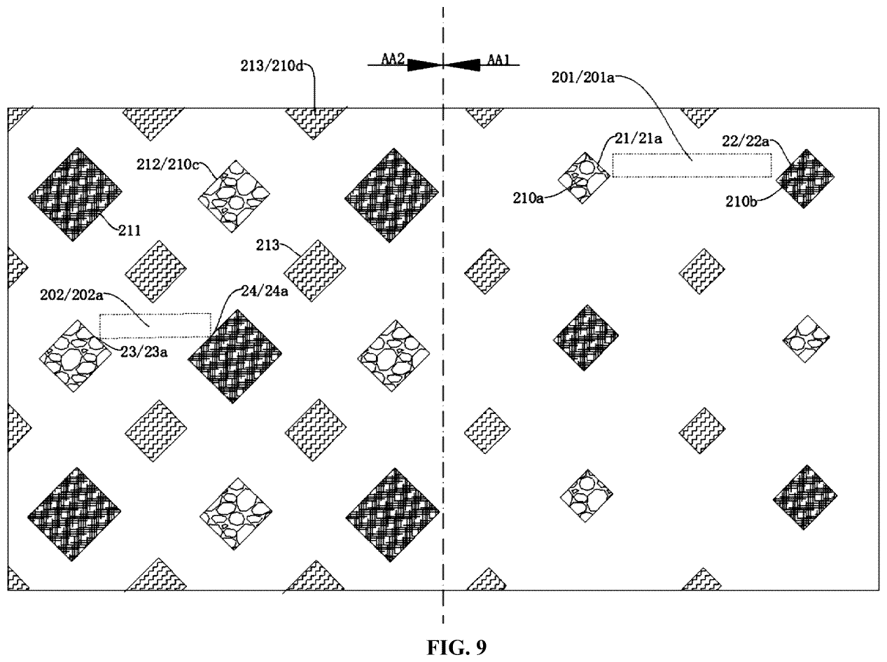

In still another some embodiment, as shown in FIG. 9, two isolation openings 210 located on two sides of the first isolation segment 201 are different from two isolation openings 210 located on two sides of the second isolation segment 202. For example, the first isolation segment 201 and the second isolation segment 202 may be located in different regions, to adjust dimensions of the isolation structure 200 in different regions and improve the display effect of the display panel 10.

In one embodiment, the multiple isolation openings 210 include a first sub-isolation opening 21, a second sub-isolation opening 22, a third sub-isolation opening 23, and a fourth sub-isolation opening 24. The second sub-isolation opening 22 is disposed adjacent to the first isolation opening 210a, and the third sub-isolation opening 23 is disposed adjacent to the fourth sub-isolation opening 24. The first isolation segment 201 may be located between the first sub-isolation opening 21and the second sub-isolation opening 22, the second isolation segment 202 is located between the third sub-isolation opening 23 and the fourth sub-isolation opening 24, and isolation openings 210 on two sides of the first isolation segment 201 are different from isolation openings 210 on two sides of the second isolation segment 202.

In one embodiment, the first sub-isolation opening 21 includes a first side wall 21a, the second sub-isolation opening 22 includes a second side wall 22a, the third sub-isolation opening 23 includes a fourth side wall 23a, and the fourth sub-isolation opening 24 includes a fifth side wall 24a. The first side wall 21a and the second side wall 22a are disposed opposite to each other, the first isolation segment 201 is located between the first side wall 21a and the second side wall 22a, the fourth side wall 23a and the fifth side wall 24a are disposed opposite to each other, and the second isolation segment 202 is located between the fourth side wall 23a and the fifth side wall 24a. Side walls on two sides of the first isolation segment 201 are also completely different from side walls on two sides of the second isolation segment 202. The fourth side wall 23a and the fifth side wall 24a being disposed opposite to each other is the same as the first side wall 21a and the second side wall 22a being disposed opposite to each other in the foregoing embodiment, which will not be repeated here.

In one embodiment, a width of the first isolation segment 201 in an arrangement direction of the first sub-isolation opening 21 and the second sub-isolation opening 22 is the first width d1, exemplarily, a minimum width of the first isolation segment 201 in the arrangement direction of the first sub-isolation opening 21 and the second sub-isolation opening 22 may be selected to be the first width d1. A width of the second isolation segment 202 in an arrangement direction of the third sub-isolation opening 23 and the fourth sub-isolation opening 24 is the second width d2, exemplarily, a width of the second isolation segment 202 in the arrangement direction of the third sub-isolation opening 23 and the fourth sub-isolation opening 24 may be selected to be the second width d2.

In one embodiment, the orthographic projection of the first isolation segment 201 on the substrate 100 and the orthographic projection of the second isolation segment 202 on the substrate 100 are disposed at intervals. The first isolation segment 201 and the second isolation segment 202 may be not connected to each other and are located in different regions, to adjust dimensions of isolation structures 200 in different regions and improve the display effect of the display panel 10.

In some embodiments, as shown in FIG. 1, the display region AA further includes a first display region AA1 and a second display region AA2 disposed around at least part of the first display region AA1.

The first display region AA1 and the second display region AA2 may be display regions used for implementing different display functions, or the first display region AA1 and the second display region AA2 may have different light transmittance. For example, a light transmittance of the first display region AA1 is greater than a light transmittance of the second display region AA2, the first display region AA1 may be a light transmittance display region, and the first display region AA1 is used for implementing the transmittable and displayable of the display panel 10, so that the photosensitive module may be integrated into the first display region AA1.

In some embodiments, as shown in FIG. 9, a pixel density of the first display region AA1 is less than a pixel density of the second display region AA2, the first isolation segment 201 is located in the first display region AA1, and the second isolation segment 202 is located in the second display region AA2.

The pixel density of the first display region AA1 refers to the number of distributed sub-pixels in a unit area of the first display region AA1, or a distribution area of sub-pixels in a unit area of the first display region AA1, that is, the number of distributed light-emitting units 310 in a unit area of the first display region AA1, or a distribution area of light-emitting units 310 in a unit area of the first display region AA1. The pixel density of the second display region AA2 is the same as that of the first display region AA1.

In these embodiments, a pixel density of the first display region AA1 is less than a pixel density of the second display region AA2, the first isolation segment 201 is located in the first display region AA1, and the second isolation segment 202 is located in the second display region AA2, so that a width of the isolation structure 200 located in the second display region AA2 is relatively small, and the pixel density of the first display region AA2 can be further increased.

In one embodiment, as shown in FIG. 9, the first isolation segment 201 includes a first sub-segment 201a located in the first display region AA1, the second isolation segment 202 includes a second sub-segment 202a located in the second display region AA2, an extension direction of the first sub-segment 201a is the same as an extension direction of the second sub-segment 202a, the first sub-segment 201a has a first width d1, and the second sub-segment 202a has a second width d2.

In these embodiments, a width of the first sub-segment 201a is different form a width of the second sub-segment 202a, and an extension direction of the first sub-segment 201a is the same as an extension direction of the second sub-segment 202a, so that a distribution shape of the isolation structure 200 of the first display region AA1 is approximate to a distribution shape of the isolation structure 200 of the second display region AA2, and thus the display difference between the first display region AA1 and the second display region AA2 can be reduced.

In one embodiment, as shown in FIG. 9, the isolation opening 210 includes a first isolation opening 210a and a second isolation opening 210b which are located in the first display region AA1, and a third isolation opening 210c and a fourth isolation opening 210d which are located in the second display region AA2, and an orthographic projection of the first sub-segment 201a on the substrate 100 is located between an orthographic projection of the first isolation opening 210a adjacent to the second isolation opening 210b on the substrate 100 and an orthographic projection of the second isolation opening 210b adjacent to the first isolation opening 210a on the substrate 100. For example, the first isolation opening 210a and the second isolation opening 210b disposed adjacent to each other have side walls disposed opposite to each other, the first sub-segment 201a is located between the opposite side walls of the first isolation opening 210a and the second isolation opening 210b and has a first width d1. The first width d1 is a width of the first sub-segment 201a in an arrangement direction of the first isolation opening 210a and the second isolation opening 210b that are adjacent to the first sub-segment 201a, that is, the width of the first sub-segment 201a in the arrangement direction of the first isolation opening 210a and the second isolation opening 210b is the first width d1. Exemplarily, the first width d1 is a minimum width of the first sub-segment 201a in the arrangement direction of the first isolation opening 210a and the second isolation opening 210b that are adjacent to the first sub-segment 201a. An orthographic projection of the second sub-segment 202a on the substrate 100 is located between an orthographic projection of the third isolation opening 210c adjacent to the fourth isolation opening 210 d on the substrate 100 and an orthographic projection of the fourth isolation opening 210d adjacent to the third isolation opening 210c on the substrate 100. Specifically, the third isolation opening 210c and the fourth isolation opening 210d that are adjacent to each other have side walls disposed opposite to each other, and the second sub-segment 202a is located between the opposite side walls of the third isolation opening 210c and the fourth isolation opening 210d and has a second width d2. The second width d2 is a width of the second sub-segment 202a in an arrangement direction of the third isolation opening 210c and the fourth isolation opening 210d that are adjacent to the second sub-segment 202a, that is, the width of the second sub-segment 202a in the arrangement direction of the third isolation opening 210c and the fourth isolation opening 210d is the second width d2. Exemplarily, the second width d2 is a minimum width of the second sub-segment 202a in the arrangement direction of the third isolation opening 210c and the fourth isolation opening 210d that are adjacent to the second sub-segment 202a. The first isolation opening 210a and the third isolation opening 210c are configured to accommodate light-emitting units 310 of the same color, and the second isolation opening 210b and the fourth isolation opening 210d are configured to accommodate light-emitting units 310 of the same color.

In these embodiments, a color of the light-emitting unit 310 in the isolation opening 210 located on two sides of the first sub-segment 201a is the same as a color of the light-emitting unit 310 in the isolation opening 210 located on two sides of the second sub-segment 202a. A color of light reflected by the first sub-segment 201a is made to be approximate to a color of light reflected by the second sub-segment 202a, so that the display difference between the first display region AA1 and the second display region AA2 can be further improved.

In one embodiment, as shown in FIG. 9, an arrangement manner of the first isolation opening 210a, the first sub-segment 201a and the second isolation opening 210b is the same as an arrangement manner of the third isolation opening 210c, the second sub-segment 202a, and the fourth isolation opening 210d, so that a difference between the light reflected by the first sub-segment 201a and the light reflected by the second sub-segment 202a is further reduced, and thus the display difference between the first display region AA1 and the second display region AA2 is improved.

The light-emitting unit 310 is disposed in various manners. For example, the light-emitting unit 310 includes a first light-emitting unit 310a, a second light-emitting unit 310b, and a third light-emitting unit 310c, and a light-emitting color of the first light-emitting unit 310a, a light-emitting color of the second light-emitting unit 310b, and a light-emitting color of the third light-emitting unit 310c are different. For example, the first light-emitting unit 310a is a blue light-emitting unit 310 and configured to emit blue light, the second light-emitting unit 310b is a red light-emitting unit 310 and configured to emit red light, and the third light-emitting unit 310c is a green light-emitting unit 310 and configured to emit green light.

In one embodiment, the isolation opening 210 includes a first opening portion 211, a second opening portion 212 and a third opening portion 213, the first light-emitting unit 310a is located in the first opening portion 211, the second light-emitting unit 310b is located in the second opening portion 212, and the third light-emitting unit 310c is located in the third opening portion 213. An arrangement rule of the first light-emitting unit 310a, the second light-emitting unit 310b and the third light-emitting unit 310c is the same as an arrangement rule of the first opening portion 211, the second opening portion 212 and the third opening portion 213.

In one embodiment, at least one of the following is satisfied: an orthographic projection area of the first opening portion 211 on the substrate 100 is greater than an orthographic projection area of the second opening portion 212 on the substrate 100, and an orthographic projection area of the first light-emitting unit 310a on the substrate 100 is greater than an orthographic projection area of the second light-emitting unit 310b on the substrate 100. For example, the first light-emitting unit 310a is a blue light-emitting unit 310, and the blue light-emitting unit 310 has a relatively large distribution area, so that the service life of the blue light-emitting unit 310 can be increased. Optionally, at least one of the following is satisfied: the orthographic projection area of the second opening portion 212 on the substrate 100 is greater than an orthographic projection area of the third opening portion 213 on the substrate 100, and the orthographic projection area of the second light-emitting unit 310b on the substrate 100 is greater than an orthographic projection area of the third light-emitting unit 310c on the substrate 100. For example, the second light-emitting unit 310b is a red light-emitting unit 310, the third light-emitting unit 310c is a green light-emitting unit 310, and the green light-emitting unit 310 has a relatively small distribution area, so that the display effect of the display panel 10 can be ensured to be balanced.

In some embodiments, as shown in FIG. 6 to FIG. 8, two first opening portions 211 and two first opening portions 211 are alternately located at four corners of a first virtual quadrangle K, and the third opening portion 213 is located within the first virtual quadrangle K.

In these embodiments, two first opening portions 211 and two second opening portions 212 alternately distributed are disposed on a peripheral side of the third opening portion 213, so that a distance between the third opening portion 213 and the first opening portion 211 and a distance between the third opening portion 213 and the second opening portion 212 can be reduced.

In one embodiment, the first virtual quadrangle K has a first side with a largest length, the first isolation segment 201 is located between the first opening portion 211 and the second opening portion 212 at two ends of the first side, the second isolation segment 202 is located between the second opening portion 212 and the third opening portion 213, or the second isolation segment 202 is located between the first opening portion 211 and the third opening portion 213.

In these embodiments, the first isolation segment 201 is located on the first side of the first virtual quadrangle K, the second isolation segment 202 is located within the first virtual quadrangle K, the first isolation segment 201 is located between two isolation openings 210 with a larger distance, and the second isolation segment 202 is located between isolation openings 210 with a smaller distance, so that the first width d1 is greater than the second width d2.

In one embodiment, the first virtual quadrangle K is a trapezoid and has a top side and a bottom side distributed at intervals in the second direction Y, a length of the top side is less than a length of the bottom side, and a distance between the first opening portion 211 and the second opening portion 212 at two ends of the bottom side is greater than a distance between the first opening portion 211 and the second opening portion 212 at two ends of the top side. The first isolation segment 201 is located between the first opening portion 211 and the second opening portion 212 at the two ends of the bottom side, the second isolation segment 202 is located between the second opening portion 212 and the third opening portion 213 in the first virtual quadrangle K, or the second isolation segment 202 is located between the first opening portion 211 and the third opening portion 213.

In still another some embodiment, in some optional embodiments, as shown in FIG. 1, the multiple isolation openings 210 are arranged in an array in the first direction X and the second direction Y, the first isolation segment 201 is located between two adjacent rows of isolation openings 210, and the second isolation segment 202 is located between two adjacent columns of isolation openings 210.

In these embodiments, an arrangement manner of the multiple isolation openings 210 is simpler, the distribution positions of the first isolation segment 201 and the second isolation segment 202 are more regular, and the setting and forming is convenient.

In some embodiments, as shown in FIG. 1, multiple first opening portions 211, multiple second opening portions 212 and multiple third openings are sequentially arranged in the first direction X to form a first opening row H1, the multiple first opening portions 211 are sequentially arranged in the second direction Y to form a first opening column L1, the multiple second opening portions 212 are sequentially arranged in the second direction Y to form a second opening column L2, and the multiple third openings 213 are sequentially arranged in the second direction Y to form a third opening column L3.

The first isolation segment 201 is located between two adjacent first opening rows H1, at least one of the following is satisfied: the second isolation segment 202 is located between the first opening column L1 and the second opening column L2 adjacent to each other, the second isolation segment 202 is located between the second opening column L2 and the third opening column L3 adjacent to each other, and the second isolation segment 202 is located between the third opening column L3 and the first opening column L1 adjacent to each other.

In these embodiments, the first opening portion 211, the second opening portion 212 and the third opening portion 213 are sequentially arranged to form the first opening row H1. Adjacent first opening rows H1 are disposed in alignment to form the first opening row L1, the second opening column L2 and the third opening column L3, the first isolation segment 201 is disposed between two adjacent first opening rows H1, and the second isolation segment 202 is disposed between two adjacent opening columns, so that distances between the first opening portion 211, the second opening portion 212 and the third opening portion 213 in the same first opening row H1 can be reduced, and thus the display effect can be improved. The first isolation segment 201 is disposed between two adjacent first opening rows H1, to increase a distance between the two adjacent first opening rows H1.

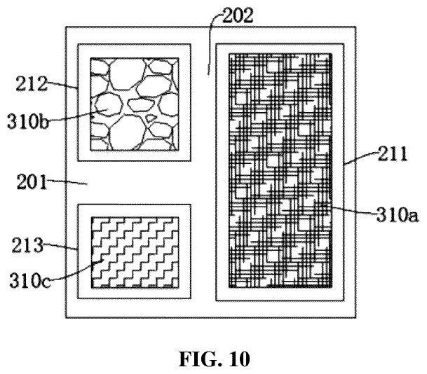

In still another some embodiments, as shown in FIG. 10, the display panel 10 further includes an opening repeating unit, where the opening repeating unit includes a first opening group and a second opening group disposed side by side in the first direction X, the first opening group includes a second opening portion 212 and a third opening portion 213 arranged in the second direction Y, and the second opening group includes a first opening portion 211 extending in the second direction Y. The first isolation segment 201 is located between the second opening portion 212 and the third opening portion 213 of the first opening group, and the second isolation segment 202 is located between the first opening portion 211 and the second opening portion 212, or the second isolation segment 202 is located between the first opening portion 211 and the third opening portion 213.

In these embodiments, the first isolation segment 2011 is located within the second opening group, and the second isolation segment 202 may be located between the first opening group and the second opening group.

In one embodiment, an extension dimension of the first opening group in the second direction Y is equal to an extension dimension of the first opening portion 211 in the second opening group in the second direction Y, the extension dimension of the first opening group in the second direction Y includes an extension dimension of the second opening portion 212 in the second direction Y, an extension dimension of the third opening portion 213 in the second direction Y, and an extension dimension of a gap between the second opening portion 212 and the third opening portion 213 in the second direction Y, so that the arrangement of the multiple isolation openings 210 is more regular and balanced, and thus the display effect can be improved.

The light-emitting unit 310 is disposed in various manners. In some optional embodiments, as shown in FIG. 1 to FIG. 8, the light-emitting unit 310 includes a first electrode 311, a light-emitting structure 312 and a second electrode 313 that are disposed in a stacked manner in a direction facing away from the substrate 100. One of the first electrode 311 and the second electrode 313 is an anode, the other of the first electrode 311 and the second electrode 313 is a cathode, and the first electrode 311 and the second electrode 313 interact with each other to drive the light-emitting structure 312 to emit light. The embodiments of the present application are illustrated by using the first electrode 311 as an anode and the second electrode 313 as a cathode as an example.

In one embodiment, the substrate 100 includes a drive unit 110 and a first insulating layer 120 disposed on a side of the drive unit 110. The first electrode 311 is disposed on a side of the first insulating layer 120 facing away from the drive unit 110. Optionally, the first insulating layer 120 may be a planarization layer.

In one embodiment, as shown in FIG. 1 to FIG. 8, a connection via hole 121 is disposed on the first insulating layer 120, and the first electrode 311 and the drive unit 110 are electrically connected to each other through the connection via hole 121, so that the drive unit 110 may send a control signal to the first electrode 311, and the drive unit 110 can drive the light-emitting unit 310 to emit light.

In one embodiment, the light-emitting structure 312 is located within the pixel opening 420, and an orthographic projection of the first electrode 311 on the substrate 100 at least partially overlaps with an orthographic projection of the pixel opening 420 on the substrate 100, so that the first electrode 311 may contact the light-emitting structure 312 in the pixel opening 420. For example, the orthographic projection of the pixel opening 420 on the substrate 100 is located within the orthographic projection of the first electrode 311 on the substrate 100, so that the light-emitting structures 312 within the pixel opening 420 can all be in contact with and connected to the first electrode 311, and thus the effective light-emitting area of the light-emitting unit 310 can be increased.

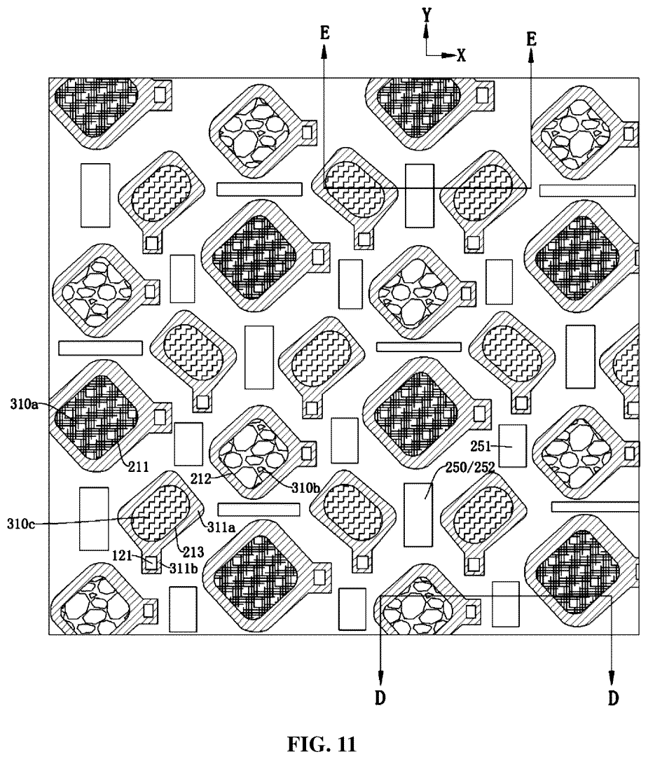

In some embodiments, as shown in FIGS. 11 to 13, an orthographic projection of the connection via hole 121 on the substrate 100 at least partially overlaps with an orthographic projection of the at least one first isolation segment 201 on the substrate 100.

In these embodiments, the first isolation segment 201 may also cover at least part of the connection via hole 121, and the connection via hole 121 is located below the first isolation segment 201, so that the flatness of the area of the pixel defining portion 410 except the first isolation segment 201 can be improved, the flatness of the surface on which the second electrode 313 is disposed can be improved, and the yield of the second electrode 313 can be further improved.

In one embodiment, the orthographic projection of the connection via hole 121 on the substrate 100 is located within the orthographic projection of the first isolation segment 201 on the substrate 100. That is, the first isolation segment 201 completely covers the connection via hole 121, so that the first isolation segment 201 can provide the complete protection for the connection via hole 121.

In one embodiment, the multiple light-emitting units 310 include multiple first electrodes 311, and each of the first electrodes 311 is connected to a respective one of the drive units 110 through a respective connection via hole. The first electrodes 311 and the connection via holes 121 are disposed in an one-to-one correspondence manner. The first isolation segment 201 may cover one connection via hole 121, that is, an orthographic projection of one connection via hole 121 on the substrate 100 at least partially overlaps with the orthographic projection of the first isolation segment 201 on the substrate 100.

In another some embodiments, as shown in FIGS. 11 to 13, orthogonal projections of connection via holes 121 corresponding to at least two first electrodes 311 on the substrate 100 at least partially overlap with an orthogonal projection of the same first isolation segment 201 on the substrate 100.

The first electrode 311 is correspondingly disposed with the connection via hole 121, that is, the first electrode 311 is connected to the drive unit 110 via the connection via hole 121.

In these embodiments, the connection via holes 121 corresponding to the at least two first electrodes 311 are covered by the first isolation segment 201, so that the arrangement of the connection via holes 121 is more concentrated, thereby facilitating the appropriate reduction of the distribution area of the first isolation segment 201, further increasing the distribution area of the second isolation segment 202, reducing the overall distribution area of the isolation structure 200, increasing the distribution area of the isolation openings 210, and increasing the aperture ratio of the display panel 10.

In one embodiment, when the multiple isolation openings 210 are arranged to form the first virtual quadrangle K, in some optional embodiments, the orthographic projection of the at least one connection via hole 121 on the substrate 100 is located at the side of the first virtual quadrangle K.

In these embodiments, the connection via hole 121 is disposed between the first opening portion 211 and the second opening portion 212. The connection via hole 121 may make at least one of the first electrode 311 of the first light-emitting unit 310a within the first opening portion 211 and the first electrode 311 of the second light-emitting unit 310b within the second opening portion 212 to be connected to the drive unit 110. The connection via hole 121 disposed between adjacent third opening portions 213 may make the first electrode 311 of the third light-emitting unit 310c within the third opening portion 213 to be connected to the drive unit 110, thereby achieving the first electrodes 311 of different light-emitting units 310 are electrically connected to the drive units 110.

In one embodiment, two connection via holes 121 are correspondingly disposed between the first opening portion 211 and the second opening portion 212 that are adjacent to each other in the first direction X. One of the two connection via holes 121 is a connection via hole 121 corresponding to the first light-emitting unit 310a within the first opening portion 211 or a connection via hole 121 corresponding to the second light-emitting unit 310b in the second opening portion 212, and the other of the two connection via holes 121 is a connection via hole 121 corresponding to the third light-emitting unit 310c within the third opening portion 213.

In these embodiments, two connection via holes 121 are disposed between the first opening portion 211 and the second opening portion 212 that are adjacent to each other in the first direction X. One of the two connection via holes 121 makes the first electrode 311 of the third light-emitting unit 310c within the third opening portion 213 to be connected to the drive unit 110, and the other of the two connection via holes 121 makes the first electrode 311 corresponding to the light-emitting unit 310 within the first opening portion 211 or the second opening portion 212 to be connected to the drive unit 110, so that not only a distance between the connection via hole 121 and the first electrode 311 corresponding to the connection via hole 121 can be reduced, but also the connection via hole 121 can be made to be arranged in a centralized manner, thereby reducing the distribution area of the first isolation segment 201 as much as possible to increase the distribution area of the isolation opening 210 and improve the aperture ratio of the display panel 10.

In one embodiment, no connection via hole 121 may be disposed between the first opening portion 211 and the second opening portion 212 that are adjacent to each other in the second direction Y. When the display panel 10 has a light-transmitting hole 250, for example, when the light-transmitting hole 250 is disposed on the isolation structure 200, this position may be configured to dispose the light-transmitting hole 250 to increase the light transmittance of the display panel 10. Optionally, no connection via hole 121 is disposed between the third opening portion 213 and the first opening portion 211 or the second opening portion 212 adjacent to the third opening portion 213, that is, no connection via hole 121 may be disposed within the first virtual quadrangle K, so that a distance between the third opening portion 213 and the isolation opening 210 adjacent to the third opening portion 213 can be reduced, and further the aperture ratio of the display panel 10 can be improved.

In any one of the foregoing embodiments, when the first electrode 311 is electrically connected to the drive unit 110 through the connection via hole 121, the first electrode 311 may extend integrally and cover the connection via hole 121, so that the first electrode 311 is electrically connected to the drive unit 110 via the connection via hole 121.

In another some embodiments, as shown in FIG. 11 and FIG. 13, the first electrode 311 includes a body portion 311a and a protruding portion 311b formed by protruding the body portion 311a, and the protruding portion 311b is via connected to the drive unit 110 by using the connection via hole 121.

In these embodiments, the first electrode 311 includes a body portion 311a and a protruding portion 311b, and the body portion 311a may be correspondingly disposed with the light-emitting structure 312 to drive the light-emitting structure 312 to emit light. The protruding portion 311b may be disposed corresponding to the connection via hole 121, so that the first electrode 311 is electrically connected to the drive unit 110 via the connection via hole 121 through the projection protruding 311b.

In one embodiment, the protruding portion 311b is disposed in a first preset direction and projects out of the body portion 311a, an extension width of the body portion 311a in a second preset direction is greater than an extension width of the protruding portion 311b in the second preset direction, and the second preset direction intersects the first preset direction. For example, when the protruding portion 311b and the body portion 311a are disposed side by side in the first direction X, the first preset direction is the first direction X, the second preset direction is the second direction Y, and an extension width of the protruding portion 311b in the second direction Y is less than an extension width of the body portion 311a in the second direction Y, to reduce the distribution area of the first electrode 311. When the protruding portion 311b and the body portion 311a are disposed side by side in the second direction Y, the first preset direction is the second direction Y, and the second preset direction is the first direction X.

In some embodiments, as shown in FIG. 11 to FIG. 15, the light-transmitting hole 250 is disposed on the first isolation segment 201.

In these embodiments, a position of the isolation opening 210 is properly adjusted, so that a part of the isolation structure 200 forms a second isolation segment 202 with a relatively small width, and another part of the isolation structure 200 forms a first isolation segment 201 with a relatively large width. The first isolation segment 201 has a relatively large width, so that a dimension of the light-transmitting hole 250 disposed in the first isolation segment 201 may be set to be relatively large, the distribution area of light-transmitting hole 250 can be increased, and thus the light transmittance of the display panel 10 can be improved.

In one embodiment, the orthographic projection of the connection via hole 121 on the substrate 100 at least partially overlaps with an orthographic projection of at least one first isolation segment 201 in which the light-transmitting hole 250 is disposed on the substrate 100. That is, the connection via hole 121 and the light-transmitting hole 250 are correspondingly disposed in the same first isolation segment 201, so that the shape of the isolation structure 200 can be simplified.

In one embodiment, the orthographic projection of the connection via hole 121 on the substrate 100 is located within an orthographic projection of the first isolation segment 201 in which the light-transmitting hole 250 is disposed on the substrate 100, to further simplify the shape of the isolation structure 200.

As described above, the light-emitting unit 310 includes a first light-emitting unit 310a, a second light-emitting unit 310b and a third light-emitting unit 310c, and the isolation opening 210 includes a first opening portion 211, a second opening portion 212 and a third opening portion 213. Two first opening portions 211 and two first opening portions 211 are alternately located at four top corners of the first virtual quadrangle K, the third opening portion 213 is located within the first virtual quadrangle K, the light-transmitting hole 250 may be located on one side of the first virtual quadrangle K, and the light-transmitting hole 250 is located between the first opening portion 211 and the second opening portion 212 adjacent to each other, to increase the distribution area of the light-transmitting hole 250 as much as possible and further improve the aperture ratio of the display panel 10.

In one embodiment, the first virtual quadrangle K includes a top side, a bottom side and two lateral sides connecting the top side and the bottom side. A length of the top side of the first virtual quadrangle K, a length of the bottom side of the first virtual quadrangle K, and a length of each of the two lateral sides connecting the top side and the bottom side of the first virtual quadrangle K are all greater than a distance between the first opening portion 211 and the third opening portion 213 or a distance between the second opening portion 212 and the third opening portion 213. The light-transmitting hole 250 includes a first sub-hole 251 and a second sub-hole 252, the first sub-hole 251 is located on at least one of the top side and the bottom side, and the second sub-hole 252 is located on the lateral side. In these optional embodiments, at least one of the top side and the bottom side, and the lateral sides of the first virtual quadrangle K are each provided with the light-transmitting hole 250, so that the distribution area of the light-transmitting hole 250 can be increased as much as possible, and further the aperture ratio of the display panel 10 can be improved.

As described above, as shown in FIGS. 11 to 14, the light-transmitting hole 250 is located between the first opening portion 211 and the second opening portion 212 adjacent to each other on the side of the first virtual quadrangle K. As described above, when the first opening portion 211, the second opening portion 212 and the third opening portion 213 are arranged along the first virtual quadrangle K, a spacing between the third opening portion 213 and the isolation opening 210 located on the peripheral side of the third opening portion 213 is relatively small, and a spacing between the first opening portion 211 and the second opening portion 212 adjacent to each other in the first direction X or the second direction Y is relatively large; therefore, the light-transmitting hole 250 is disposed between the first opening portion 211 and the second opening portion 212 adjacent to each other, so that the distribution area of the light-transmitting hole 250 can be increased as much as possible, and thus the aperture ratio of the display panel 10 can be improved.

In some embodiments, the light-transmitting hole 250 include a first sub-hole 251 and a second sub-hole 252. Optionally, the first virtual quadrangle K includes two first lateral sides disposed at intervals in the first direction X and two second lateral sides disposed at intervals in the second direction Y. The first sub-hole 251 is located at the second lateral side, and the second sub-hole 252 is located at the first lateral side.

In these embodiments, the light-transmitting hole 250 includes a first sub-hole 251 and a second sub-hole 252, so that the distribution area of the light-transmitting hole 250 can be increased, and thus the light transmittance of the display panel 10 can be improved.

In one embodiment, the first isolation segment 201 includes a seventh sub-segment and an eighth sub-segment. The seventh sub-segment is provided with the first sub-hole 251, and the eighth sub-segment is provided with the second sub-hole 252. Different light-transmitting holes 250 are disposed on different first isolation segments 201.

In any one of the above-described embodiments, the display panel 10 may only include the connection via hole 121, the orthographic projection of the first isolation segment 201 on the substrate 100 at least partially overlaps with the orthographic projection of the connection via hole 121 on the substrate 100, that is, no light-transmitting hole 250 is disposed on the first isolation segment 201, and the first isolation segment 201 is only configured to cover the connection via hole 121.

In one embodiment, the display panel 10 may only include the light-transmitting hole 250, i.e., the first isolation segment 201 may only be configured to be provided with the light-transmitting hole 250, i.e., the first isolation segment 201 may not cover the connection via hole 121, and the first isolation segment 201 is configured to dispose the light-transmitting hole 250.

In one embodiment, in still another some embodiments, the display panel 10 includes not only the connection via hole 121, but also includes the light-transmitting hole 250. In these optional embodiments, part of the first isolation segment 201 may cover at least part of the connection via hole 121, and another part of the first isolation segment 201 is configured to be provided with the light-transmitting hole 250.

In one embodiment, when the display panel 10 includes not only the connection via hole 121 but also includes the light-transmitting hole 250, as shown in FIGS. 11 to 15, the same first isolation segment 201 is not only configured to cover at least part of the connection via hole 121, but also configured to be provided with the light-transmitting hole 250, so that the function of the first isolation segment 201 can be enriched, the structure of the display panel 10 can be simplified, and the aperture ratio of the display panel 10 can be increased on the basis of ensuring the light transmittance of the display panel 10.

In one embodiment, an orthographic projection of at least one connection via hole 121 on the substrate 100 and an orthographic projection of at least one light-transmitting via 250 on the substrate 100 are located within orthographic projections of two adjacent isolation openings 210 on the substrate 100. In this case, the first isolation segment 201 located between the two adjacent isolation openings 210 not only covers at least part of the connection via hole 121, but also is provided with the light-transmitting hole 250.

As described above, when the light-emitting unit 310 includes the first light-emitting unit 310a, the second light-emitting unit 310b and the third light-emitting unit 310c, the isolation opening 210 includes a first opening portion 211, a second opening portion 212 and a third opening portion 213, the first virtual quadrangle K is formed in the above-described arrangement manner, an orthographic projection of at least one connection via hole 121 on the substrate 100 and an orthographic projection of at least one light-transmitting hole 250 on the substrate 100 are located between an orthographic projection of the first opening portion 211 on the substrate 100 and an orthographic projection of the second opening portion 212 on the substrate 100, where the first opening portion 211 and the second opening portion 212 are adjacent to each other in the first direction X.

In these embodiments, not only the connection via hole 121, but also the light-transmitting hole 250 is correspondingly disposed between the first opening portion 211 and the second opening portion 212 which are adjacent to each other in the first direction X, so that the first isolation segment 201 at this position can not only cover the connection via hole 121 and but also can be configured to be provided with the light-transmitting hole 250, whereby the structure of the display panel 10 can be simplified, and the aperture ratio of the display panel 10 can be increased on the basis of ensuring the light transmittance of the display panel 10.

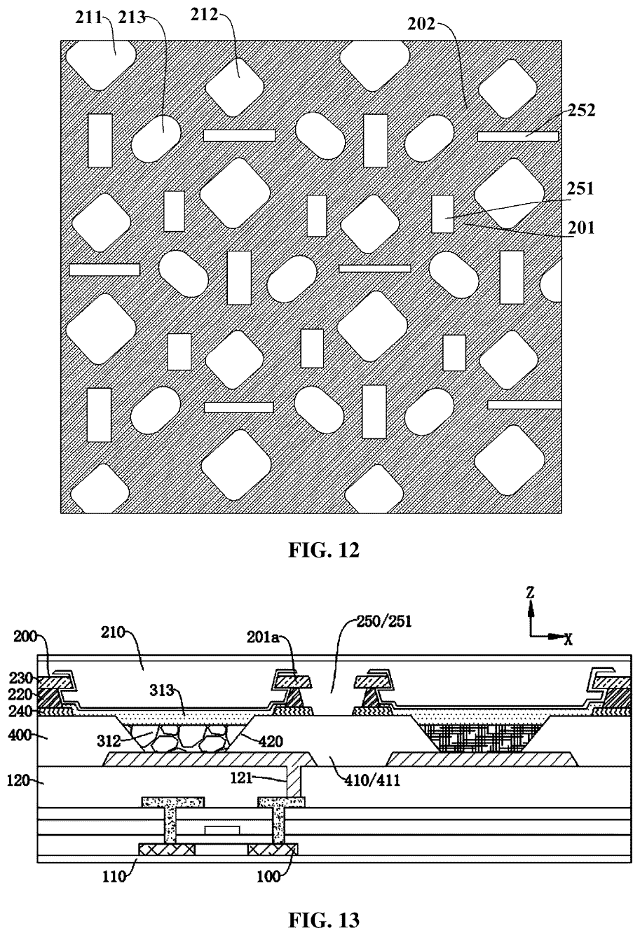

In one embodiment, as shown in FIGS. 11 and 12, when the first opening portion 211, the second opening portion 212 and the third opening portion 213 form the first virtual quadrangle K in the above-described arrangement manner, a gap is formed between the first opening portion 211 and the second opening portion 212 adjacent to each other in the first direction X, and the gap is also located between two adjacent third opening portions 213 in the second direction Y. Therefore, the orthographic projection of at least one connection via hole 121 on the substrate 100 and the orthographic projection of at least one light-transmitting hole 250 on the substrate 100 are located between the orthographic projection of the first opening portion 211 on the substrate 100 and the orthographic projection of the second opening portion 212 on the substrate 100, where the first opening portion 211 and the second opening portion 212 are adjacent to each other in the first direction X, and are located between orthographic projections of two adjacent third opening portions 213 in the second direction Y on the substrate 100.

In these embodiments, the gap is formed between the first opening portion 211 and the second opening portion 212 adjacent to each other in the first direction X, and the gap is also located between two adjacent third openings 213 within the fifth opening column L5 in the second direction Y. At least one connection via hole 121 and the light-transmitting hole 250 are disposed in the gap, so that the structure of the display panel 10 can be simplified, and the aperture ratio of the display panel 10 can be increased on the basis of ensuring the light transmittance of the display panel 10.

In one embodiment, as described above, when two connection via holes 121 are located between the first opening portion 211 and the second opening portion 212 adjacent to each other in the first direction X and between two adjacent third opening portions 213 in the second direction Y, and the light-transmitting hole 250 may be further disposed within the gap. For example, orthographic projections of two connection via holes 121 on the substrate 100 and the orthographic projection of at least one light-transmitting hole 250 on the substrate 100 are located between an orthographic projection of the first opening portion 211 on the substrate 100 and an orthographic projection of the second opening portion 212 on the substrate 100, where the first opening portion 211 and the second opening portion 212 are adjacent to each other within the second opening row H2 in the first direction X, and are located between orthographic projections of two adjacent third opening portions 213 within the fifth opening row L5 in the second direction Y on the substrate 100.

In these embodiments, the gap is formed between the first opening portion 211 and the second opening portion 212 adjacent to each other in the first direction X, and the gap is also located between two adjacent third opening portions 213 in the second direction Y. Not only two connection via holes 121 are disposed within the gap, but also at least one light-transmitting hole 250 is disposed within the gap. One of the two connection via holes 121 may make the first electrode 311 of the light-emitting unit 310 within the first opening portion 211 or the second opening portion 212 located on a side of this connection via hole in the first direction X to be connected to the drive unit 110, the other of the two connection via holes 121 may make the first electrode 311 of the third light-emitting unit 310c within the third opening portion 213 located on a side of this connection via hole in the second direction Y to be connected to the drive unit 110, and the light-transmitting hole 250 is configured to improve the light transmittance of the display panel 10.

In one embodiment, as described above, when the light-transmitting hole 250 includes the first sub-hole 251 and the second sub-hole 252, the first sub-hole 251 is located between the first opening portion 211 and the second opening portion 212 adjacent to each other in the first direction X, the first sub-hole 251 and two connection via holes 121 may be correspondingly located between the first opening portion 211 and the second opening portion 212 adjacent to each other in the first direction X, and the second sub-hole 252 is located between the first opening portion 211 and the second opening portion 212 adjacent to each other in the second direction Y. That is, an orthographic projection of the first sub-hole 251 on the substrate 100 and orthographic projections of two connection via holes 121 on the substrate 100 are located between the orthographic projection of the first opening portion 211 on the substrate 100 and the orthographic projection of the second opening portion 212 on the substrate 100, where the first opening portion 211 and the second opening portion 212 are adjacent to each other in the first direction X, and are located between orthographic projections of two adjacent third opening portions 213 in the second direction Y on the substrate 100, and the second sub-hole 252 is located between the orthographic projection of the first opening portion 211 on the substrate 100 and the orthographic projection of the second opening portion 212 on the substrate 100, where the first opening portion 211 and the second opening portion 212 are adjacent to each other in the second direction Y.

In these embodiments, two connecting via holes 121 and the first sub-hole 251 are correspondingly disposed between the first opening portion 211 and the second opening portion 212 adjacent to each other in the first direction X, and the second sub-hole 252 is correspondingly disposed between the first opening portion 211 and the second opening portion 212 adjacent to each other in the second direction Y. Positions of the connection via hole 121 and the light-transmitting hole 250 are reasonably arranged so that not only the aperture ratio of the display panel 10 can be improved, and but also the light transmittance of the display panel 10 can be increased.

In one embodiment, an orthographic projection area of the second sub-hole 252 on the substrate 100 is greater than an orthographic projection area of the first sub-hole 251 on the substrate 100. In these optional embodiments, the orthographic projection area of the first sub-hole 251 on the substrate 100 is relatively small, so that the first sub-hole 251 can provide a yielding position for the connection via hole 121, and moreover, the orthographic projection area of the second sub-hole 252 on the substrate 100 is relatively large, so that the light transmittance of the display panel 10 can be further improved.

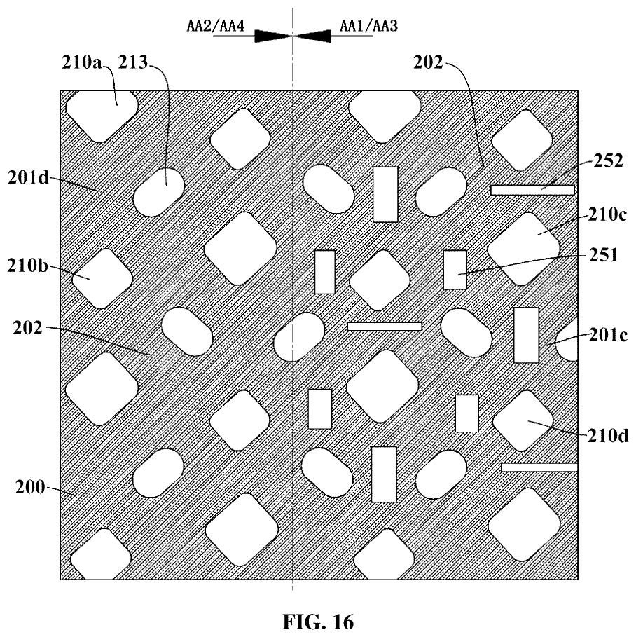

In one embodiment, as shown in FIG. 16, the light-transmitting hole 250 is located in the first display region AA1, and the first isolation segment 201 provided with the light-transmitting hole 250 is located in the first display region AA1, to improve the light transmittance of the first display region AA1.

In one embodiment, the display region AA further includes a third display region AA3 and a fourth display region AA4 connected to each other, and a light transmittance of the third display region AA3 is greater than a light transmittance of the fourth display region AA4. A pixel density of the third display region AA3 may be the same as or different from a pixel density of the fourth display region AA4.

In one embodiment, the first isolation segment 201 includes a fifth sub-segment 201c located in the third display region AA3, and a width of the fifth sub-segment 201c is greater than a width of the second isolation segment 202. That is, the fifth sub-segment 201c is located in the third display region AA3 and is configured to be provided with the light-transmitting hole 250, to increase the light transmittance of the third display region AA3. And/or, the first isolation segment 201 includes a sixth sub-segment 201d located in the fourth display region AA4, an orthogonal projection of the sixth sub-segment 201d on the substrate 100 is staggered with the orthographic projection of the light-transmitting hole 250 on the substrate 100, and a width of the sixth sub-segment 201d is greater than a width of the second isolation segment 202. The first isolation segment 201 includes a sixth sub-segment 201d that is located in the fourth display region AA4 and has a relatively large width, and the second isolation segment 202 with the relatively small width is located in the third display region AA3, to improve the light transmittance of the third display region AA3.

In one embodiment, the second isolation segment 202 is disposed in at least one of the third display region AA3 and the fourth display region AA4, to ensure an aperture ratio of the display panel 10.

In one embodiment, when pixel openings 420 on two sides corresponding to the fifth sub-segment 201c and the sixth sub-segment 201d are configured to accommodate light-emitting units 310 of the same color, a width of the fifth sub-segment 201c may be the same as a width of the sixth sub-segment 201d. In other embodiments, a width of the fifth sub-segment 201c may also be different from a width of the sixth sub-segment 201d.

In one embodiment, in order to further improve the display effect of the display panel 10, the isolation opening 210 includes a first isolation opening 210a and a second isolation opening 210b that are located in the third display region AA3, and a third isolation opening 210c and a fourth isolation opening 210d that are located in the fourth display region AA4. An orthographic projection of the fifth sub-segment 201c on the substrate 100 is located between the orthographic projection of the first isolation opening 210a adjacent to the second isolation opening 210b on the substrate 100 and the orthographic projection of the second isolation opening 210b adjacent to the first isolation opening 210a on the substrate 100, an orthographic projection of the sixth sub-segment 201d on the substrate 100 is located between an orthographic projection of the third isolation opening 210c adjacent to the fourth isolation opening 210d on the substrate 100 and an orthographic projection of the fourth isolation opening 210d adjacent to the third isolation opening 210c on the substrate 100, the first isolation opening 210a and the third isolation opening 210c are configured to accommodate light-emitting units 310 of the same color, and the second isolation opening 210b and the fourth isolation opening 210d are configured to accommodate light-emitting units 310 of the same color.

In these embodiments, a color of the light-emitting unit 310 within the isolation opening 210 located on two sides of the fifth sub-segment 201c is the same as a color of the light-emitting unit 310 within the isolation opening 210 located on two sides of the sixth sub-segment 201d. The fifth sub-segment 201c and the sixth sub-segment 201d are each an isolation segment with a relatively large width, so that light amounts reflected by the fifth sub-segment 201c are approximate to light amounts reflected by the sixth sub-segment 201d. Moreover, A color of the reflected light of the fifth sub-segment 201c is also approximate to a color of the reflected light of the sixth sub-segment 201d, so that the display difference between the third display region AA3 and the fourth display region AA4 can be further improved.

In one embodiment, an arrangement manner of the first isolation opening 210a, the second isolation opening 210b and the fifth sub-segment 201c on the substrate 100 is the same as an arrangement manner of the third isolation opening 210c, the fourth isolation opening 210d and the sixth sub-segment 201d on the substrate 100. For example, in a view direction shown in FIG. 16, the first isolation opening 210a is located on an upper side of the fifth sub-segment 201c in the second direction Y, and the third isolation opening 210c is located on an upper side of the sixth sub-segment 201d in the second direction Y. The second isolation opening 210b is located on a lower side of the fifth sub-segment 201c in the second direction Y, and the fourth isolation opening 210d is located on a lower side of the sixth sub-segment 201d in the second direction Y.

In these embodiments, a position of the sixth sub-segment 201d and a position of the fifth sub-segment 203 are properly disposed, so that a light color and a light amount reflected by the fifth sub-segment 201c is approximate to a light color and a light amount reflected by the sixth sub-segment 201d, and the display difference between the third display region AA3 and the fourth display region AA4 can be better improved.

In one embodiment, a width of the fifth sub-segment 201c is the same as a width of the sixth sub-segment 201d.

In these embodiments, the width of the fifth sub-segment 201c is the same as the width of the sixth sub-segment 201d. On the one hand, the display effect of the third display region AA3 is approximate to the display effect of the fourth display region AA4, and on the other hand, a distribution shape of the isolation structure 200 of the third display region AA3 is approximate to a distribution shape of the isolation structure 200 of the fourth display region AA4, whereby the overall distribution shape of the isolation structure 200 can be simplified, the preparation process of the isolation structure 200 can be simplified, and thus the preparation efficiency of the display panel 10 can be improved.

In some embodiments, as described above, with continued reference to FIG. 1 to FIG. 16, when the display panel 10 includes the pixel defining layer 400, the isolation structure 200 may be located on a side of the pixel defining portion 410 facing away from the substrate 100, and the pixel defining portion 410 of the display region AA includes a first defining section 411 and a second defining section 412. An orthographic projection of the first isolation segment 201 on the substrate 100 is located within an orthographic projection of the first defining section 411 on the substrate 100, an orthographic projection of the second isolation segment 202 on the substrate 100 is located within an orthographic projection of the second defining section 412 on the substrate 100, the first defining section 411 has a third width c1, the second defining section 412 has a fourth width c2, and the third width c1 is greater than the fourth width c2.

In these embodiments, a dimension of the first isolation segment 201 is adapted to a dimension of the first defining section 411, and a dimension of the second isolation segment 202 is adapted to a dimension of the second defining section 412, so that a setting dimension of the pixel defining portion 410 is adapted to a setting dimension of the isolation structure 200, and thus the yield of the display panel 10 can be improved.

In one embodiment, a width direction of the first defining section 411 is an arrangement direction of two pixel openings 420 located on two sides of the first defining section 411. The third width c1 is an extension dimension in the width direction of the first defining section 411. For example, when two pixel openings 420 are disposed side by side in the first direction X and the first defining section 411 is located between two pixel openings 420 disposed side by side in the first direction X and extends in the second direction Y, a width of the first defining section 411 is a width of the first direction X, and an arrangement manner of a width direction of the second defining section 412 is the same as an arrangement manner of a width direction of the first defining section 411, which will not be repeated here. The fourth width c2 is an extension dimension in the width direction of the second defining section 412.

In one embodiment, the first isolation segment 201 may be located on a side of the first defining section 411 facing away from the substrate 100, and the second isolation segment 202 is located on a side of the second defining section 412 facing away from the substrate 100.

In one embodiment, in the pixel openings 420 and the isolation openings 210 communicating with each other, orthographic projections of edges of the pixel opening 420 on the substrate 100 are located within orthographic projection contours of edges of the isolation openings 210 on the substrate 100. That is, in the pixel openings 420 and the isolation openings 210 communicating with each other, a region enclosed and formed by an orthographic projection of an inner wall surface facing the pixel opening 420 of the pixel defining portion 410 on the substrate 100 is located in a region enclosed and formed by an orthographic projection of an inner wall surface facing the isolation opening 210 of the isolation structure 200 on the substrate 100, to improve the shielding of the isolation structure 200 from light.

In one embodiment, in the pixel openings 420 and the isolation openings 210 communicating with each other, orthographic projections of edges of the pixel openings 420 on the substrate 100 and orthographic projections of edges of the isolation openings 210 on the substrate 100 are at least partially disposed at equal intervals, so that distances between the orthographic projections of the edges of the isolation openings 210 on the substrate 100 and the orthographic projections of the edges of the pixel openings 420 on the substrate 100 and at different positions on peripheral sides of the pixel openings 420 are equal, where the pixel openings 420 communicate with the isolation openings 210, so that the shielding effect of the isolation structure 200 on the light emitting tends to be consistent, and thus the uniformity of the display effect can be improved.

In another some embodiments, when the pixel defining portion 410 includes an avoidance opening, the avoidance opening is enclosed and formed by the first defining section 411 and the second defining section 412, the first isolation segment 201 is located within the avoidance opening enclosed and formed by the first defining section 411, and the second isolation segment 202 is located within the avoidance opening enclosed and formed by the second defining section 412.

In some embodiments, as shown in FIG. 1 to FIG. 14, the display panel 10 further includes a first encapsulation layer 510, and the first encapsulation layer 510 includes a first encapsulation portion 511 located on a side of the light-emitting units 310 facing away from the substrate 100. The first encapsulation portion 511 is configured to provide the encapsulation protection for the light-emitting units 310. For example, when the light-emitting unit 310 includes the first electrode 311, the light-emitting structure 312 and the second electrode 313, the first encapsulation portion 511 may be located on a side of the second electrode 313 facing away from the light-emitting structure 312.

In one embodiment, the first encapsulation portion 511 is located on a side of the light-emitting unit 310 facing away from the substrate 100, the first encapsulation portion 511 extends from the isolation opening 210 to a side of the isolation structure 200 facing away from the substrate 100, a sealing gap 512 located on the side of the isolation structure 200 facing away from the substrate 100 is formed between two adjacent first encapsulation portions. The sealing gap 512 located on a side of the first isolation segment 201 facing away from the substrate 100 has a fifth width W1, and the sealing gap 512 located on a side of the second isolation segment 202 facing away from the substrate 100 has a sixth width W2, and the fifth width W1 is greater than the sixth width W2. Reference is made to the third width c1 and the fourth width c2 for the fifth width W1 and the sixth width W2, which will not be repeated here.

In these embodiments, when the first width d1 is greater than the second width d2, the fifth width W1 may be made to be greater than the sixth width W2, that is, the sealing gap 512 on the relatively wide isolation structure 200 is relatively wide, so that a dimension of the first encapsulation portion 511 is more adaptable to a dimension of the isolation structure 200.

In one embodiment, orthographic projection areas of at least two first encapsulation portions 511 on the substrate 100 are different, so that different first encapsulation portions 511 can be adapted to light-emitting units 310 of different dimensions.

In one embodiment, the first encapsulation portion 511 may include a first segment located within the isolation opening 210 and a second segment extending to the side of the isolation structure 200 facing away from the substrate 100, and the first segment and the second segment are disposed integrally to provide more sealed protection for the light-emitting unit 310 within the isolation opening 210.

In one embodiment, when the display panel 10 includes the first isolation segment 201 and the second isolation segment 202 that have different widths, orthographic projection areas of at least two first encapsulation portions 511 on the substrate 100 are different, so that the second segment of the first encapsulation portion 511 can cover the first isolation segment 201 or the second isolation segment 202, and thus the sealing effect of the first encapsulation portion 511 can be ensured.

In one embodiment, the display panel 10 further includes a second encapsulation layer 520, and the second encapsulation layer 520 is located on a side of the first encapsulation layer 510 facing away from the substrate 100. The second encapsulation layer 520 may be an entire structure layer, and the second encapsulation layer 520 may be configured to cover the entire display region of the display panel 10. Optionally, the display panel 10 may further include a third encapsulation layer 530 located on a side of the second encapsulation layer 520 facing away from the substrate 100, and the third encapsulation layer 530 may cover the second encapsulation layer 520. Materials of the first encapsulation layer 510 and the third encapsulation layer 530 may include an inorganic material, and a material of the second encapsulation layer 520 may include an organic material.

In one embodiment, when the display panel 10 includes the first encapsulation layer 510 and the first encapsulation portion 511 described above, the first encapsulation portion 511 extends from the isolation opening 210 to the side of the isolation structure 200 facing away from the substrate 100, a sealing gap 512 located on the side of the isolation structure 200 facing away from the substrate 100 is formed between two adjacent first encapsulation portions 511, and a width of the sealing gap 512 located on the side of the first isolation segment 201 facing away from the substrate 100 is greater than a width of the sealing gap 512 located on the side of the second isolation segment 202 facing away from the substrate 100. That is, second segments of the adjacent first encapsulation portions 511 forms the sealing gap 512 is formed between second segments on the side of the isolation structure 20 facing away from the substrate 100 of adjacent first encapsulation portions 511. A dimension of the sealing gap 512 is proportional to a width of the first isolation segment 201 and a width of the second isolation segment 202, so that the sealing effect can be improved.

In one embodiment, as described above, the isolation opening 210 includes a first opening portion 211, a second opening portion 212 and a third opening portion 213, an orthographic projection area of the first opening portion 211 on the substrate 100 is greater than an orthographic projection area of the second opening portion 212 on the substrate 100, and an orthographic projection area of the second opening portion 212 on the substrate 100 is greater than an orthographic projection area of the third opening portion 213 on the substrate 100.

In one embodiment, the first encapsulation portion 511 includes a first encapsulation unit covering at least part of the first opening portion 211, a second encapsulation unit covering at least part of the second opening portion 212, and a third encapsulation unit covering at least part of the third opening portion 213. An orthographic projection area of the first encapsulation unit on the substrate 100 is greater than an orthographic projection area of the second encapsulation unit on the substrate 100, and the orthographic projection area of the second encapsulation unit on the substrate 100 is greater than an orthographic projection area of the third encapsulation unit on the substrate 100, so that each encapsulation unit can be adapted to a dimension of each opening portion, and thus the sealing effect is ensured.

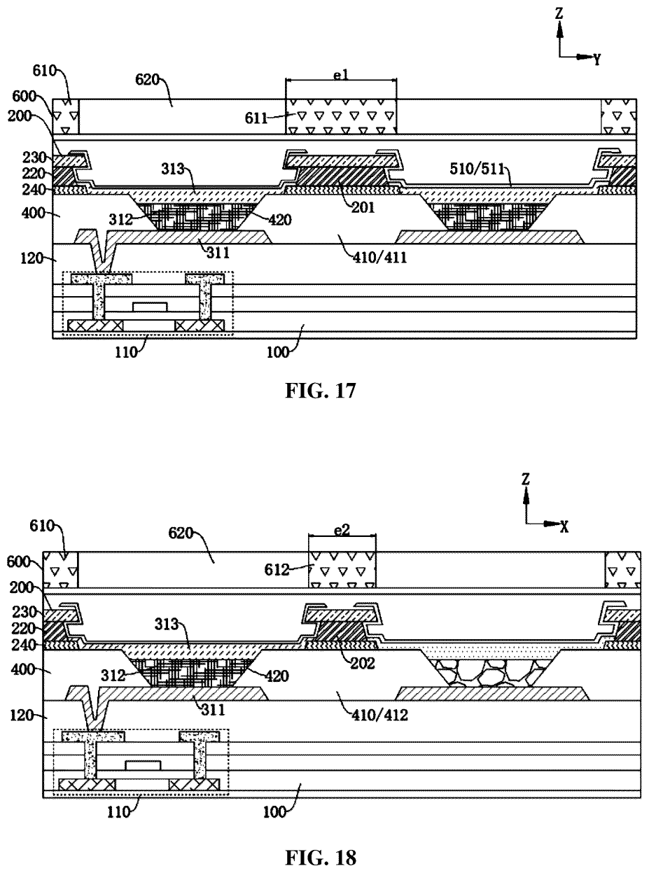

In some embodiments, as shown in FIG. 1, FIG. 17 and FIG. 18, the display panel 10 further includes a light-filtering layer 600 located on a side of the light-emitting layer 300 facing away from the substrate 100. The light-filtering layer 600 includes a light-shielding portion 610 and a light-filtering opening enclosed and formed by the light-shielding portion 610. A light-filtering unit 620 is disposed within the light-filtering opening, and an orthographic projection of the light-filtering unit 620 on the substrate 100 at least partially overlaps with an orthographic projection of the light-emitting unit 310 on the substrate 100. The light-shielding portion 610 includes a first light-shielding section 611 located on a side of the first isolation segment 201 facing away from the substrate 100 and a second light-shielding section 612 located on a side of the second isolation segment 202 facing away from the substrate 100, the first light-shielding section 611 has a seventh width e1, the second light-shielding section 612 has an eighth width e2, and the seventh width e1 is greater than the eighth width e2. For, reference is made to the third width c1 and the fourth width c2 for the seventh width e1 and the eighth width e2, which will not be repeated here.

In these embodiments, the seventh width e1 is greater than the eighth width e2, so that a dimension of the first light-shielding section 611 is adapted to a dimension of the first isolation segment 201, and a dimension of the second light-shielding section 612 is adapted to the dimension of the second isolation segment 202, so that the light transmittance and the display effect of the display panel 10 cam be further improved.

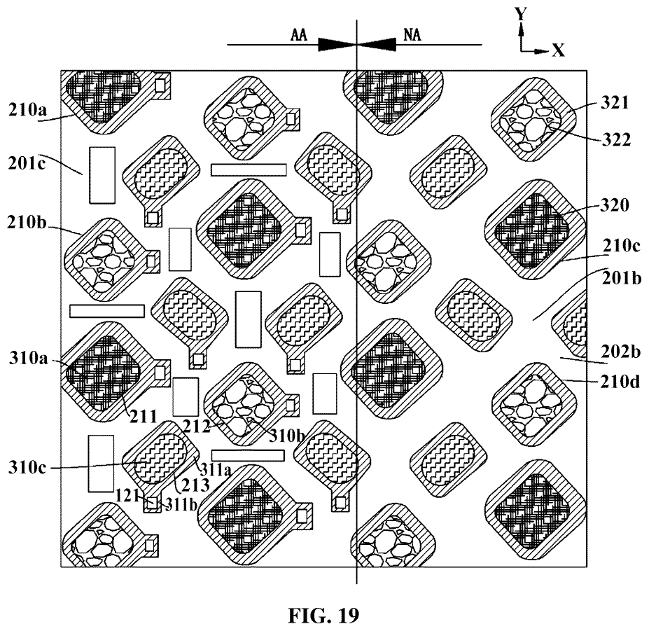

In some embodiments, as shown in FIG. 19, at least one isolation opening 210 is located in the non-display region NA, the light-emitting layer 300 includes a virtual light-emitting unit 320 located in the isolation opening 210 within the non-display region NA. The isolation structure 200 includes a third sub-segment 201b and a fourth sub-segment 202b located in the non-display region NA, and an orthographic projection of the third sub-segment 201b on the substrate 100 and an orthographic projection of the fourth sub-segment 202b on the substrate 100 are located between two adjacent isolation openings 210. The third sub-segment 201b of the isolation structure 200 has a ninth width, the fourth segment 202b of the isolation structure 200 has a tenth width, and the ninth width is greater than the tenth width.

Reference may be made to the first width for an arrangement manner of the ninth width and the tenth width, which will not be repeated here.

In these embodiments, the third sub-segment 201b and the fourth sub-segment 202b are disposed within the non-display region NA, so that the distribution pattern of the isolation structure 200 within the non-display region NA may be approximate to the distribution pattern of the isolation structure 200 within the display region AA, thereby improving the uniformity of display.

In one embodiment, an arrangement rule of the multiple isolation openings 120 in the display region AA is the same as an arrangement rule of the multiple isolation openings 120 in the non-display region NA, so that the distribution pattern of the isolation structure 200 in the non-display region NA is approximate to the distribution pattern of the isolation structure 200 in the display region AA, thereby better improving the uniformity of display in the breath screen state.

A sectional shape of the isolation structure 200 may be disposed in various manners, for example, the cross-section of the isolation structure 200 is formed in a rectangular shape or an inverted trapezoidal shape, that is, an orthographic projection of a surface of the isolation structure 200 facing the substrate 100 on the substrate 100 is located within an orthographic projection of a surface of the isolation structure 200 facing away from the substrate 100 on the substrate 100, so that the material of the light-emitting structure 312 facilitates the formation of light-emitting structures 312 independent of each other by breaking at the edge of the isolation opening 210.

In another some embodiments, as shown in FIG. 1 to FIG. 18, the isolation structure 200 includes a first sub-layer 220 and a second sub-layer 230 located on a side of the first sub-layer 220 facing away from the substrate 100, and an orthographic projection of the first sub-layer 220 on the substrate 100 is located within an orthographic projection of the second sub-layer 230 on the substrate 100.

In these embodiments, a dimension of the first sub-layer 220 is less than a dimension of the second sub-layer 230, so that an inward recess is formed on a side of the second sub-layer 230 facing the substrate 100. When a luminescent material is dropped onto the isolation structure 200, the luminescent material tends to break at the edge of the second sub-layer 230 facing the isolation opening 210, and further the light-emitting structures 312 which are located in the isolation openings 210 and are independent of each other are formed, so that the precision mask process can be omitted, the preparation process of the display panel 10 can be simplified, and the preparation efficiency of the display panel 10 can be improved.

In one embodiment, a width b1 of the second sub-layer 230 of the first isolation segment 201 is greater than a width b2 of the second sub-layer 230 of the second isolation segment 202, so that the width of the first isolation segment 201 is greater than the width of the second isolation segment 202.

In one embodiment, a width a1 of the first sub-layer 220 of the first isolation segment 201 is greater than a width a2 of the first sub-layer 220 of the second isolation segment 202, so that a dimension of the first sub-layer 220 of the first isolation segment 201 is more adapted to a dimension of the second sub-layer 230 of the first isolation segment 201, a width of the first sub-layer 220 of the second isolation segment 202 is more adapted to a width of the second sub-layer 230 of the second isolation segment 202, and the width of the first isolation segment 201 is greater than the width of the second isolation segment 202.

In still another some embodiments, the isolation structure 200 further includes a third sub-layer 240 located on a side of the first sub-layer 220 facing the substrate 100, and the orthographic projection of the first sub-layer 220 on the substrate 100 is located within an orthographic projection of the third sub-layer 240 on the substrate 100.

In these embodiments, the isolation structure 200 further includes a third sub-layer 240, and a dimension of the third sub-layer 240 is greater than a dimension of the first sub-layer 220. In the preparation process of the isolation structure 200, the first sub-layer 220 is carved laterally so that the dimension of the first sub-layer 220 is less than the dimension of the second sub-layer 230, the third sub-layer 240 can provide protection for a film layer located on the side of the first sub-layer 220 facing the substrate 100, so that the yield of the display panel 10 can be ensured.

In one embodiment, when the isolation structure 200 includes the third sub-layer 240, a width d1 of the third sub-layer 240 of the first isolation segment 201 is greater than a width d2 of the third sub-layer 240 of the first isolation segment 201. In these optional embodiments, a dimension of the third sub-layer 240 of the first isolation segment 201 is more adapted to the dimension of the first sub-layer 220 of the first isolation segment 201 and the dimension of the second sub-layer 230 of the first isolation segment 201, and a dimension of the third sub-layer 240 of the second isolation segment 202 is more adapted to a dimension of the first sub-layer 220 of the second isolation segment 202 and a dimension of the second sub-layer 230 of the second isolation segment 202, so that the yield of the isolation structure 200 can be improved.

For example, in one embodiment, a material of the first sub-layer 220 includes a conductive material, and the first sub-layer 220 is electrically connected to the second electrodes 313, so that the second electrodes 313 of the multiple light-emitting units 310 may be connected to each other as planar electrodes through the first sub-layers 220.

In one embodiment, a material of the second sub-layer 230 includes a conductive material, to increase the distribution area of the conductive material and reduce voltage drops of the second electrode 313 at different positions in the display region.

In one embodiment, a material of the third sub-layer 240 includes a conductive material, and the third sub-layer 240 is in contact with and connected to the second electrode 313, to increase the distribution area of the conductive material and reduce voltage drops of the second electrode 313 at different positions in the display region.

In one embodiment, the first isolation segment 201 and the second isolation segment 202 refer to the structures of the isolation structure 200 in different regions, that is, on a surface parallel to a display surface of the display panel 10, portions of the isolation structure 200 in different positions include the first isolation segment 201 and the second isolation segment 202. The first sub-layer 220, the second sub-layer 230 and the third sub-layer 240 (if any) refer to that the isolation structure 200 includes different film layer structures disposed in a stacked manner in a cross section in a thickness direction Z of the display surface. The isolation structures 200 in the different regions, that is, the first isolation segment 201 and the second isolation segment 202, may each include the first sub-layer 220, the second sub-layer 230 and the third sub-layer 240 (if any).

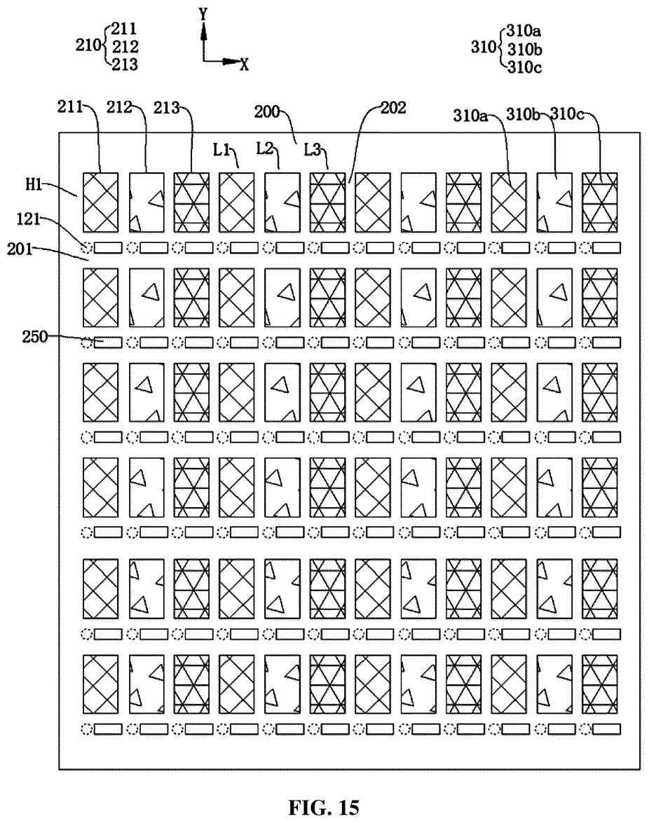

In one embodiment, as shown in FIG. 15, when the first opening portion 211, the second opening portion 212 and the third opening portion 213 are arranged in the above-described manner to form the first opening row H1, the first opening column L1, the second opening column L2 and the third opening column L3, the connection via hole 121 is located between two adjacent first opening rows H1, so that the first electrode 311 of the first light-emitting unit 310a in the first opening row H1, the first electrode 311 of the second light-emitting unit 310b in the first opening row H1, and the first electrode 311 of the third light-emitting unit 310c in the first opening row H1 may be connected to the drive unit 110 through the connection via hole 121.

In one embodiment, as shown in FIG. 15, the connection via hole 121 is disposed between any two adjacent first opening rows H1, and the arrangement of the multiple connecting via holes 121 is more uniform, so that the arrangement of the first opening portions 211, the second opening portions 212 and the third opening portions 213 is more balanced, and the display effect of the display panel 10 can be improved.

In one embodiment, as shown in FIG. 15, when the display panel 10 includes the light-transmitting hole 250, an orthogonal projection of the light-transmitting holes 250 on the substrate 100 may be located within orthogonal projections of two adjacent first opening rows H1 on the substrate 100. For example, when the display panel 10 includes the light-transmitting hole 250 and the connection via hole 121, the orthographic projection of the light-transmitting hole 250 on the substrate 100 may be located between orthographic projections of two adjacent connection via holes 121 in the first direction X on the substrate 100, so that the distribution of the connection via hole 121 and the distribution of the transparent via hole 250 are more uniform.

In one embodiment, the display panel 10 includes the display region AA and the non-display region NA. The light-emitting unit 310 is located in the display region AA, and at least one isolation opening 210 is located in the non-display region NA. The light-emitting layer 300 includes a virtual light-emitting unit 320 located in the isolation opening 210 within the non-display region NA, and no light-transmitting hole 250 is disposed on the first isolation segment 201 in the non-display region NA. The structure of the virtual light-emitting unit 320 may be the same as the structure of the light-emitting unit 310, and the virtual light-emitting unit 320 is not used for light emission. The virtual light-emitting unit 320 includes a virtual light-emitting structure 322 and a first virtual electrode 321 located on a side of the virtual light-emitting structure 322 facing the substrate 100, and the first virtual electrode 321 is not connected to the driver circuit structure in the array substrate 100. A second virtual electrode and a virtual encapsulation portion may be disposed on a side of the virtual light-emitting structure 322 facing away from the substrate 100.

As shown in FIG. 1 to FIG. 19, an embodiment of the first aspect of the present application further provides a display panel 10. The display panel 10 is divided into a display region AA and a non-display region NA which are connected to each other. The display panel 10 includes: a substrate 100; a pixel defining layer 400, where the pixel defining layer 400 is disposed on the substrate 100 and includes a pixel defining portion 410 and pixel openings 420; an isolation structure 200, where the isolation structure 200 is disposed on a side of the pixel defining portion 410 facing away from the substrate 100, the isolation structure 200 is provided with isolation openings 210, and each of the isolation openings 210 communicate with a respective one of the pixel openings 420. The pixel defining portion 410 located in the display region AA includes a first defining section 411 and a second defining section 412, an orthographic projection of the first defining section 411 on the substrate 100 and an orthographic projection of the second defining section 412 on the substrate 100 are located between orthographic projections of two adjacent pixel openings 420 on the substrate 100, the first defining section 411 has a third width, the second defining section 412 has a fourth width, and the third width is greater than the fourth width.

In these embodiments, the third width is greater than the fourth width so that a width of part of the isolation structure 200 disposed on the first defining section 411 is greater than a width of the isolation structure 200 disposed on the second defining section 412. Widths of the isolation segments in different regions of the isolation structure 200 are adjusted, so that dimensions of the isolation openings 210 in different regions can be adjusted, and further the display effect of the display panel 10 can be adjusted, thereby improving the use performance of the display panel 10.

In one embodiment, the display panel 10 of the embodiments of the present application and the above-described display panel 10 may be referred to each other, which will not be repeated here. For example, the display panel 10 includes the first isolation subsection 201 and the second isolation subsection 202 described above, the first isolation subsection 201 has a first width, the second isolation subsection 202 has a second width, and the first width is greater than the second width.

As shown in FIG. 1 to FIG. 19, the present application further provides a display device. The display device includes any of the display panels 10 provided in the above-described embodiments of the present application.

The display device provided in the present application may further include a photosensitive module. The photosensitive module is integrated into the display panel 10 or is located on a side of the substrate 100 facing away from the light-emitting layer 300, whereby the light transmittance of the display panel 10 is improved, so that the photosensitive module can better receive the light to improve the working yield of the photosensitive module.

The display device may be a mobile terminal such as a mobile phone or a notebook computer, or a fixed terminal such as a television or a computer monitor, or may also be a wearable device such as a watch, which is not particularly limited in the present application.

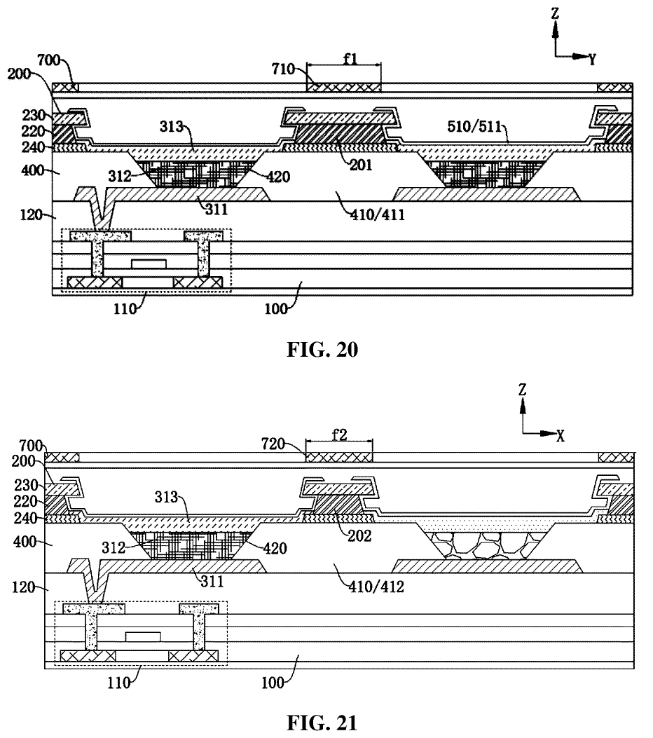

In one embodiment, as shown in FIG. 20 and FIG. 21, the display device further includes a touch electrode 700. The touch electrode 700 includes a first touch segment 710 located on a side of the first isolation segment 201 facing away from the substrate 100 and a second touch segment 720 located on a side of the second isolation segment 202 facing away from the substrate 100, where a width f1 of the first touch segment 710 is equal to a width f2 of the second touch segment 720, whereby the distribution of the touch electrodes 700 is more uniform, and thus a condition that different voltage drops of the touch electrodes 700 at different positions lead to different touch effects is improved.

According to the above-described embodiments of the present application, all details are not described in detail in these embodiments, and these embodiments are also not limited to only specific embodiments of the present disclosure. Apparently, many modifications and changes may be made according to the foregoing description. This specification selects and specifically describes these embodiments to better explain principles and practical applications of the present application, so that those skilled in the art can make a good use of the present application and the amendment made on the basis of the present application. The present application is only limited by the claims and all the scope and equivalents thereof.

What is claimed is:

1. A display panel, wherein the display panel is divided into a display region and a non-display region connected to each other, and the display panel comprises:
a substrate;
an isolation structure, wherein the isolation structure is disposed on a side of the substrate, and a plurality of isolation openings are enclosed and formed by the isolation structure; and
a light-emitting layer, wherein the light-emitting layer comprises a plurality of light-emitting units disposed on the display region and a light-emitting unit among the plurality of light-emitting units is located in an isolation opening among the plurality of isolation openings,
wherein the isolation structure located in the display region comprises a first isolation segment and a second isolation segment, an orthographic projection of the first isolation segment on the substrate and an orthographic projection of the second isolation segment on the substrate are located between orthographic projections of two adjacent isolation openings among the plurality of isolation openings on the substrate, the first isolation segment has a first width, the second isolation segment has a second width, and the first width is greater than the second width.

2. The display panel of claim 1, wherein the first isolation segment and the second isolation segment are located between a same group of two adjacent isolation openings among the plurality of isolation openings; and
an extension direction of the first isolation segment is the same as an extension direction of the second isolation segment.

3. The display panel of claim 1, wherein one of two isolation openings located on two sides of the first isolation segment and one of two isolation openings located on two sides of the second isolation segment are a same isolation opening.

4. The display panel of claim 1, wherein two isolation openings located on two sides of the first isolation segment are different from two isolation openings located on two sides of the second isolation segment;
the plurality of isolation openings comprise a first sub-isolation opening, a second sub-isolation opening, a third sub-isolation opening and a fourth sub-isolation opening, wherein the second sub-isolation opening is disposed adjacent to the first isolation opening, the third sub-isolation opening is disposed adjacent to the fourth sub-isolation opening, the first sub-isolation opening comprises a first side wall, the second sub-isolation opening comprises a second side wall, the third sub-isolation opening comprises a fourth side wall, and the fourth sub-isolation opening comprises a fifth side wall, wherein the first side wall and the second side wall are disposed opposite to each other, the first isolation segment is located between the first side wall and the second side wall, the fourth side wall and the fifth side wall are disposed opposite to each other, and the second isolation segment is located between the fourth side wall and the fifth side wall.

5. The display panel of claim 1, further comprising a first display region and a second display region, a pixel density of the first display region is less than a pixel density of the second display region, the first isolation segment is located in the first display region, and the second isolation segment is located in the second display region;
the first isolation segment comprises a first sub-segment located in the first display region, the second isolation segment comprises a second sub-segment located in the second display region; an extension direction of the first sub-segment is the same as an extension direction of the second sub-segment, the first sub-segment has the first width, and the second sub-segment has the second width.

6. The display panel of claim 1, wherein the plurality of light-emitting units comprise a first light-emitting unit, a second light-emitting unit and a third light-emitting unit, the plurality of isolation openings comprise a first opening portion, a second opening portion and a third opening portion, the first light-emitting unit is located at the first opening portion, the second light-emitting unit is located at the second opening portion, and the third light-emitting unit is located at the third opening portion;
two first opening portions and two second opening portions are alternately located at four corners of a first virtual quadrangle, and the third opening portion is located within the first virtual quadrangle; and
a side with a maximum length in the first virtual quadrangle is a first side, the first isolation segment is located between the first opening portion and the second opening portion at two ends of the first side, and the second isolation segment is located between the first opening portion and the third opening portion, or the second isolation segment is located between the second opening portion and the third opening portion.

7. The display panel of claim 1, wherein the plurality of isolation openings are arranged in an array in a first direction and a second direction, the first isolation segment is located between two adjacent rows of isolation openings, and the second isolation segment is located between two adjacent columns of isolation openings;
the plurality of light-emitting units comprise a first light-emitting unit, a second light-emitting unit and a third light-emitting unit, the plurality of isolation openings comprise a first opening portion, a second opening portion and a third opening portion, the first light-emitting unit is located at the first opening portion, the second light-emitting unit is located at the second opening portion, and the third light-emitting unit is located at the third opening portion;
a plurality of first opening portions, a plurality of second opening portions and a plurality of third opening portions are sequentially arranged in the first direction to form a first opening row, a plurality of first opening portions are sequentially arranged in the second direction to form a first opening column, a plurality of second opening portions are sequentially arranged in the second direction to form a second opening column, and a plurality of third opening portions are sequentially arranged in the second direction to form a third opening column;
the first isolation segment is located between two adjacent first opening rows; and
at least one of the following is satisfied:
the second isolation segment is located between a first opening column and a second opening column adjacent to each other, the second isolation segment is located between the second opening column and the third opening column adjacent to each other, and the second isolation segment is located between first opening column and third opening column adjacent to each other.

8. The display panel of claim 1, wherein the plurality of light-emitting units comprise a first light-emitting unit, a second light-emitting unit and a third light-emitting unit;
the plurality of the isolation openings form a plurality of opening repeating units, at least one of the plurality of opening repeating units comprises a first opening group and a second opening group disposed side by side in a first direction, the first opening group comprises a second opening portion and a third opening portion arranged in a second direction, the second opening group comprises a first opening portion extending in the second direction, the first light-emitting unit is located at the first opening portion, the second light-emitting unit is located at the second opening portion, and the third light-emitting unit is located at the third opening portion;
the first isolation segment is located between the second opening portion of the first opening group and the third opening portion of the first opening group; and
the second isolation segment is located between the first opening portion and the second opening portion, or the second isolation segment is located between the first opening portion and the third opening portion.

9. The display panel of claim 1, wherein,
a light-emitting unit of the light-emitting units comprises a first electrode, a light-emitting structure and a second electrode, wherein the first electrode, the light-emitting structure and the second electrode are disposed in a stacked manner in a direction facing away from the substrate; and
the substrate comprises a plurality of drive units and a first insulating layer disposed on a side of a drive unit facing the light-emitting layer, the first insulating layer is provided with a plurality of connection via holes, and the first electrode and the drive unit are electrically connected to each other via a respective connection via hole among the plurality of connection via holes.

10. The display panel of claim 9, wherein orthographic projections of connection via holes corresponding to at least two first electrodes on the substrate at least partially overlap with an orthographic projection of a same first isolation segment on the substrate.

11. The display panel of claim 1, wherein at least part of the first isolation segment is provided with a light-transmitting hole; and
the orthographic projection of the second isolation segment on the substrate is staggered with an orthographic projection of the light-transmitting hole on the substrate.

12. The display panel of claim 11, wherein,
the plurality of light-emitting units comprise a first light-emitting unit, a second light-emitting unit and a third light-emitting unit, the plurality of isolation openings comprise a first opening portion, a second opening portion and a third opening portion, the first light-emitting unit is located at the first opening portion, the second light-emitting unit is located at the second opening portion, and the third light-emitting unit is located at the third opening portion;
two first opening portions and two second opening portions are alternately located at four corners of a first virtual quadrangle, and the third opening portion is located within the first virtual quadrangle;
the light-transmitting hole is located on at least one side of the first virtual quadrangle, and the light-transmitting hole is located between the first opening portion and the second opening portion adjacent to each other; and
the first virtual quadrangle comprises a top side, a bottom side and two lateral sides connecting the top side and the bottom side, the light-transmitting hole comprises a first sub-hole and a second sub-hole, the first sub-hole is located on at least one of the top side and the bottom side, and the second sub-hole is located on the lateral sides.

13. The display panel of claim 1, further comprising a pixel defining layer disposed on the substrate, wherein the isolation structure is located on a side of the pixel defining layer facing away from the substrate, the pixel defining layer comprises a pixel defining portion and a plurality of pixel openings enclosed and formed by the pixel defining portion, a pixel opening communicates with a respective isolation opening, the pixel defining portion comprises a first defining section and a second defining section, an orthographic projection of the first isolation segment on the substrate is located within an orthographic projection of the first defining section on the substrate, an orthographic projection of the second isolation segment on the substrate is located within an orthographic projection of the second defining section on the substrate, the first defining section has a third width, the second defining section has a fourth width, and the third width is greater than the fourth width.

14. The display panel of claim 1, further comprising a first encapsulation layer, wherein the first encapsulation layer comprises a plurality of first encapsulation portions, the plurality of first encapsulation portions are located on a side of the plurality of light-emitting units facing away from the substrate, a first encapsulation portion of the plurality of first encapsulation portions extend from a respective isolation opening of the plurality of isolation openings to a side of the isolation structure facing away from the substrate, and
at least one of the following is satisfied:
a sealing gap located on the side of the isolation structure facing away from the substrate is formed between two adjacent first encapsulation portions among the plurality of first encapsulation portions, the sealing gap located on a side of the first isolation segment facing away from the substrate has a fifth width, the sealing gap on a side of the second isolation segment facing away from the substrate has a sixth width, and the fifth width is greater than the sixth width; and
orthographic projection areas of at least two first encapsulation portions among the plurality of first encapsulation portions on the substrate are different.

15. The display panel of claim 1, wherein the display panel comprises a light-filtering layer located on a side of the light-emitting layer facing away from the substrate, wherein the light-filtering layer comprises a light-shielding portion and a plurality of light-filtering openings enclosed and formed by the light-shielding portion, a light-filtering unit is disposed within a light-filtering opening among the plurality of light-filtering openings, an orthographic projection of the light-filtering unit on the substrate at least partially overlaps with an orthographic projection of the light-emitting unit on the substrate, the light-shielding portion comprises a first light-shielding section located on a side of the first isolation segment facing away from the substrate and a second light-shielding section located on a side of the second isolation segment facing away from the substrate, the first light-shielding section has a seventh width, the second light-shielding section has an eighth width, and the seventh width is greater than the eighth width; or
wherein the light-emitting layer further comprises a plurality of virtual light-emitting units located in the plurality of isolation openings within the non-display region, the isolation structure located within the non-display region comprises a third sub-segment and a fourth sub-segment, an orthographic projection of the third sub-segment on the substrate and an orthographic projection of the fourth sub-segment on the substrate are located between orthographic projections of two adjacent isolation openings on the substrate, the third sub-segment has a ninth width, the fourth sub-segment has a tenth width, and the ninth width is greater than the tenth width; and an arrangement rule of the plurality of isolation openings in the display region is the same as an arrangement rule of the plurality of isolation openings in the non-display region.

16. The display panel of claim 1, wherein the isolation structure comprises a first sub-layer and a second sub-layer located on a side of the first sub-layer facing away from the substrate, an orthographic projection of the first sub-layer on the substrate is located within an orthographic projection of the second sub-layer on the substrate;
a width of the second sub-layer of the first isolation segment is greater than a width of the second sub-layer of the first isolation segment;
a width of the first sub-layer of the first isolation segment is greater than a width of the first sub-layer of the second isolation segment; and
the isolation structure further comprises a third sub-layer located on a side of the first sub-layer facing the substrate, an orthographic projection of the first sub-layer on the substrate is located within an orthographic projection of the third sub-layer on the substrate, and a width of the third sub-layer of the first isolation segment is greater than a width of the third sub-layer of the first isolation segment.

17. A display panel, wherein the display panel is divided into a display region and a non-display region connected to each other, and the display panel comprises:
a substrate;
a pixel defining layer, which is disposed on the substrate and comprises a pixel defining portion and pixel openings; and
an isolation structure, which is disposed on a side of the pixel defining portion facing away from the substrate, the isolation structure is provided with a plurality of isolation openings, and an isolation opening among the plurality of isolation openings communicates with at least one of the pixel openings;
wherein the pixel defining portion located in the display region comprises a first defining section and a second defining section, an orthographic projection of the first defining section on the substrate and an orthographic projection of the second defining section on the substrate are located between orthographic projections of two adjacent pixel openings on the substrate, the first defining section has a third width, the second defining section has a fourth width, and the third width is greater than the fourth width.

18. The display panel of claim 17, wherein the isolation structure located in the display region comprises a first isolation segment located on a side of the first defining section facing away from the substrate and a second isolation segment located on a side of the second defining section facing away from the substrate, the first isolation segment has a first width, the second isolation segment has a second width, and the first width is greater than a second width.

19. A display device, comprising the display panel of claim 1.

20. The display device of claim 19, further comprising a touch electrode, wherein the touch electrode comprises a first touch segment located on a side of the first isolation segment facing away from the substrate and a second touch segment located on a side of the second isolation segment facing away from the substrate, and a width of the first touch segment is equal to a width of the second touch segment.
